(19) United States
(12) Patent Application Publication
(10) Pub. No.: US 2026/0064012 A1
(43) Pub. Date: Mar. 5, 2026

(54) METHOD AND SYSTEM FOR THREE-DIMENSIONAL MODELING OF STOCHASTIC VARIATIONS OF LITHOGRAPHIC PROCESS

(71) Applicant: Siemens Industry Software Inc., Plano, TX (US)

(72) Inventors: Chih-I Wei, Leuven (BE); Azat Latypov, San Jose, CA (US); Germain Louis Fenger, Gladstone, OR (US)

(73) Assignee: Siemens Industry Software Inc., Plano, TX (US)

(21) Appl. No.: 18/819,673

(22) Filed: Aug. 29, 2024

(51) Int. Cl. G03F 7/00

(52) U.S. Cl. CPC G03F 7/70525; G03F 7/0037; G03F 7/705; G03F 7/7055

(57) ABSTRACT

A method and system for 3D modeling of stochastic variation of a lithographic process. The lithographic process is subject to random stochastic phenomena, with the resulting stochastic randomness potentially becoming a major challenge. The stochastic phenomena are modeled using a stochastic model, such as a random field model, that models stochastic randomness. To extend the application of the stochastic model to predict 3D aspects and increase the accuracy of modeling, the stochastic randomness for each level of a plurality of levels discrete from one another in a resist thickness direction may be modeled and analyzed across the plurality of level to generate a 3-dimentional distribution of the stochastic randomness. In turn, indications of 3-dimentional distribution of the stochastic randomness may be used to modify one or both of the light exposure and resist parameters in order to reduce the effect of stochastic randomness on the lithographic process.

### FIELD

The present disclosure relates to the field of circuit design and manufacturing, and specifically relates to three-dimensional modeling of stochastic variations of lithographic process.

### BACKGROUND

Electronic circuits, such as integrated microelectronics, are used in a variety of products, from automobiles to microwaves to personal computers. Designing integrated circuits (IC) typically involves many steps, sometimes referred to as a “design flow.” Following the completion of the design flow, the IC design is sent to a semiconductor fabrication plant, where the designed IC is fabricated. The particular steps of the design flow often are dependent upon the type of integrated circuit, its complexity, the design team, and the integrated circuit fabricator or foundry that will manufacture the IC. Typically, software and hardware “tools” verify the design at various stages of the design flow by running software simulators and/or hardware emulators. These steps aid in the discovery of errors in the design, and allow the designers and engineers to correct or otherwise improve the design.

For example, a layout design may be derived from an electronic circuit design. The layout design may comprise an IC layout, an IC mask layout, or a mask design. In particular, the layout design may be a representation of an integrated circuit in terms of planar geometric shapes that correspond to the patterns of metal, oxide, or semiconductor layers, which make up the components of the integrated circuit. The layout design can be one for a whole chip or a portion of a full-chip layout design.

Lithography is a process used to manufacture electronic circuits in which light is used to transfer a geometric pattern from a photomask, based on the layout design, to a silicon substrate by a photo-sensitive polymer. The polymer contains certain functional groups which get cleaved due to chemical reactions caused by exposure to light (deprotection) and hence affects the polymer's solubility during development and thus creating a mask for the subsequent etching process. Various types of lithography processes are used, including deep ultraviolet (DUV) lithography or extreme ultraviolet (EUV) lithography. In DUV or EUV lithography, one or more stochastic phenomena may manifest themselves, such as line edge roughness or critical dimension (CD) non-uniformity. In more extreme cases, the stochastic phenomena may lead to stochastic pinching or bridging of the patterned features, resulting in potential failure of the electronic circuit.

DUV lithography or EUV lithography may be subject to random stochastic phenomenon based on any one, any combination or all of: (1) photon shot noise; (2) stochastic phenomena in the resist process (e.g., for a family of photoresists known as Chemically Amplified Photoresists, these phenomena include photo-acid generator's (PAG) activation, acids/quencher molecules random walk and reactions, deprotection of the functional groups); or (3) stochastic phenomena in the resist development (e.g., dissolution of entangled partially deprotected polymer chains). While stochastic randomness effects both DUV and EUV lithography, the effects are more severe for EUV lithography due to lower average photon counts, resulting in stochastic randomness being one of the major challenges in EUV lithography.

Stochastic randomness may affect various parts of the layout design, such as features in the layout design intended to be printed and features in the layout design not intended to be printed. Merely by way of example, sub-resolution assist features (SRAFs) and main features may be included in the layout design. SRAFs are the auxiliary features (e.g., dark or bright areas on the photomask) added typically in the vicinity of the main features. The main features are intended to print the element of the integrated circuit on the wafer, usually shaped similarly to the main feature (e.g. a via or a contact hole or an interconnect wire). The SRAFs are designed so that they do not print themselves on the wafer, but help to make the printed main features to be closer to the target shapes and to be less sensitive to the perturbations of the lithographic process parameters (e.g. dose and focus). Examples of SRAFs are disclosed in US Patent Application Publication No. 2006/0240342 A1, US Patent Application Publication No. 2013/0191792 A1, and US Patent Application Publication No. 2019/0266311 A1, each of which are incorporated by reference in their entirety.

Deviations of the lithographic process parameters from their nominal values, such as due to the stochastic perturbation phenomena described in the previous section, may result in SRAF features printing themselves (e.g., sidelobe printing). As a result, unintended printed features may occur on the wafer, resulting in lithographic defects and reducing the yield of the lithographic process of the integrated circuit fabrication. Thus, methodologies seek to determine the likelihood of SRAF printability.

Various methods seek to understand stochastic randomness, for example, in order to determine the likelihood of SRAF printability. As one example, experimental measurements are used whereby multiple instances of the pattern of interest are exposed and measured, with identical exposure, development and measurement settings. The experimental measurements are then analyzed to calculate various metrics related to the success or failure frequency of the lithographic process outcome (e.g., pinching/bridging frequency, other failure frequency, CD variation histograms, etc.). In particular, multiple instances of the pattern of interest are exposed and their scanning electronic microscope (SEM) images are measured, with identical exposure, development and SEM measurement settings. The SEM measurements results are analyzed to assess the frequency of the SRAF or sidelobe printing in these multiple experimental trials.

As another example, Monte Carlo simulations are performed using stochastic rigorous models of exposure and resist processes. Specifically, multiple simulation runs (e.g., simulation trials) are run with identical exposure, development and simulated metrology settings, differing by the random seed factors used in the stochastic simulator. The outcomes of these random simulation trials are then analyzed to calculate various metrics related to the success or failure frequencies of the lithographic process outcome (e.g., the frequency of the SRAF or sidelobe printing). In particular, to optimize the mask in order to mitigate the effects of randomness, for each iteration on the mask, Monte Carlo simulations are run to estimate the probability of lithographic failures due to stochastic effects. The mask is then optimized, from one iteration to another, to reduce such estimate of failure probability.

As still another example, non-stochastic resist and exposure models may be used with modifications increasing the printability of sidelobes. In particular, for a positive resist, the value of the threshold may be lowered, or the nominal dose can be slightly increased, to cause SRAFs or sidelobe printability. The simulated printed SRAFs or sidelobes are then measured and the likelihood of their printability from stochastic perturbations is judged by the dimensions of the simulated printed SRAFs or sidelobes.

As yet another example, the probability of SRAF or sidelobe printing may be calculated in a certain area. In particular, the calculation may be performed using the stochastic model and the methods described in U.S. application Ser. No. 16/545,601, entitled “Method and System for Calculating Probability of Success or Failure for a Lithographic Process Due to Stochastic Variations of the Lithographic Process”, incorporated by reference herein in its entirety.

### SUMMARY

In one embodiment, a method, executed by at least one processor of at least one computer, for analyzing a lithographic process for imaging a portion of a layout design onto a substrate, the method comprising: accessing a random field model configured to model stochastic randomness in one or both of exposure or resist process, the random field model configured to receive inputs of at least one light exposure parameter, at least one resist model parameter associated with resist used in the lithographic process, and at least one success or failure criterion, the random field model configured to generate a probability distribution function of deprotection concentration indicative of success probability or failure probability of the lithographic process; inputting the at least one light exposure parameter, the at least one resist model parameter, and the at least one success or failure criterion to the random field model; using the random field model to model the stochastic randomness for a plurality of levels based on one or both of the at least one light exposure parameter or the at least one resist model parameter, wherein the plurality of levels are discrete from one another in a resist thickness direction; analyzing the stochastic randomness across the plurality of levels; outputting, based on the analysis of the stochastic randomness across the plurality of levels, the indication of the success probability or the failure probability of the lithographic process; and based on the indication of the success probability or the failure probability of the lithographic process, modifying at least one aspect in the lithographic process in order to reduce an effect of the stochastic randomness in the lithographic process.

In another embodiment, one or more non-transitory computer-readable media storing computer-executable instructions for causing one or more processors performance of a method comprising: accessing a random field model configured to model stochastic randomness in one or both of exposure or resist process, the random field model configured to receive inputs of at least one light exposure parameter, at least one resist model parameter associated with resist used in a lithographic process, and at least one success criterion or failure criterion, the random field model configured to generate a probability distribution function of deprotection concentration indicative of success probability or failure probability of the lithographic process; inputting the at least one light exposure parameter, the at least one resist model parameter, and the at least one success criterion or failure criterion to the random field model; using the random field model to model the stochastic randomness for a plurality of levels based on one or both of the at least one light exposure parameter or the at least one resist model parameter, wherein the plurality of levels are discrete from one another in a resist thickness direction; analyzing the stochastic randomness across the plurality of levels; outputting, based on the analysis of the stochastic randomness across the plurality of levels, the indication of the success probability or the failure probability of the lithographic process; and based on the indication of the success probability or the failure probability of the lithographic process, modifying at least one aspect in the lithographic process in order to reduce an effect of the stochastic randomness in the lithographic process.

In still another embodiment, a system is disclosed. The system includes one or more processors programmed to perform: accessing a random field model configured to model stochastic randomness in one or both of exposure or resist process, the random field model configured to receive inputs of at least one light exposure parameter, at least one resist model parameter associated with resist used in a lithographic process, and at least one success or failure criterion, the random field model configured to generate a probability distribution function of deprotection concentration indicative of success probability or failure probability of the lithographic process; inputting the at least one light exposure parameter, the at least one resist model parameter, and the at least one success or failure criterion to the random field model; using the random field model to model the stochastic randomness for a plurality of levels based on one or both of the at least one light exposure parameter or the at least one resist model parameter, wherein the plurality of levels are discrete from one another in a resist thickness direction; analyzing the stochastic randomness across the plurality of levels; outputting, based on the analysis of the stochastic randomness across the plurality of levels, the indication of the success probability or the failure probability of the lithographic process; and based on the indication of the success probability or the failure probability of the lithographic process, modifying at least one aspect in the lithographic process in order to reduce an effect of the stochastic randomness in the lithographic process.

### BRIEF DESCRIPTION OF THE DRAWINGS

The accompanying drawings, which are incorporated in and constitute a part of this specification, illustrate various aspects of the invention and together with the description, serve to explain its principles. Wherever convenient, the same reference numbers will be used throughout the drawings to refer to the same or like elements.

FIG. 1 illustrates an example of a computing system that may be used to implement various embodiments of the disclosed technology.

FIG. 2 illustrates an example of a multi-core processor unit that may be used to implement various embodiments of the disclosed technology.

FIG. 3A illustrates a block diagram of inputs to and output(s) from the stochastic model.

FIG. 3B-3C are flow diagrams of generating and using the indications of stochastic randomness for one or more areas of interest using the stochastic model.

FIGS. 4A-4C a graph of simulated SRAF related APA vs. SRAF related APA inspected using SEM images.

FIG. 5A illustrates a first resist representation without accounting for stochastic effects.

FIG. 5B illustrates the first resist representation accounting for stochastic effects.

FIGS. 6A-B illustrate the first resist representation accounting for stochastic effects using a cutline C to determine whether pinching has not occurred (FIG. 6A) or whether pinching has occurred (FIG. 6B).

FIG. 7A is an illustration of a second resist representation of grouped lines with a tip-to-tip (t2t) gap and the t2t gauge critical dimension (CD).

FIG. 7B illustrates a graph correlated to the second resist representation of FIG. 7A of the CD-based success criterion.

FIG. 7C is another illustration of the second resist representation with pinching in the t2t gap.

FIG. 7D illustrates a graph of a comparison of MVNCDF versus Monte Carlo simulations for the second resist representation of FIGS. 7A-C for ΔCD=2 nm.

FIG. 7E illustrates a graph of a comparison of MVNCDF versus Monte Carlo simulations for the second resist representation of FIGS. 7A-C for ΔCD=4 nm.

FIG. 8A illustrates a third resist representation of success probability estimation using integrity and isolation sets.

FIG. 8B is an expansion on a subsection of the third resist representation of FIG. 8A.

FIG. 9A is a graph of nominal and stochastic resist intensity calculated using different equations.

FIG. 9B is a graph of a comparison of standard deviation of intensity of each pixel calculated from 10000 random intensity profiles and the one calculated analytically.

FIG. 10A is a graph of intensity bounds for resist intensity.

FIG. 10B is a graph of the probability distribution of the edge location.

FIG. 11A is the edge's location from 100,000 random intensities, with the upper and lower bounds for the edge's location for α=3.

FIG. 11B is a graph of the percent of the edge locations inside the analytical bounds vs α.

FIG. 12A is an illustration of the shot noise sample of 2D intensity illustrating the randomized printing contour d·Ir(x,y)=T and the normal printing contour d·I(x,y)=T.

FIG. 12B is an illustration of high and low bounding contours and the sampled randomized blurred contour.

FIG. 12C is an illustration of 200 randomized contours overlapping, where one highlighted random contour did bridge.

FIG. 13 is an illustration of a sidelobe printing control domain (SPCD).

FIG. 14 is a table of SRAF-relative APA vs. dose derived from Monte Carlo simulations and from the analytical formula for the illustration in FIG. 13.

FIG. 15A is a graph of SRAF relative APA vs. dose for Monte Carlo and for analytical solutions (linear scale) for the data illustrated in FIG. 14.

FIG. 15B is a graph of SRAF relative APA vs. dose for Monte Carlo and for analytical solutions (logarithmic scale) for the data illustrated in FIG. 14.

FIG. 16 is an illustration of the sidelobe printability control domain (SPCD) for a via/contact holes (CH) case.

FIG. 17 is a table of SRAF-relative APA vs. dose derived from Monte Carlo simulations and from the analytical formula for the illustration in FIG. 16.

FIG. 18A is a graph of SRAF relative APA vs. dose for Monte Carlo and for analytical solutions (linear scale) for the data illustrated in FIG. 17.

FIG. 18B is a graph of SRAF relative APA vs. dose for Monte Carlo and for analytical solutions (logarithmic scale) for the data illustrated in FIG. 17.

### DETAILED DESCRIPTION OF EMBODIMENTS

### General Considerations

Various aspects of the present disclosed technology relate to techniques for modeling stochastic randomness in the exposure and resist process three dimensionally in order to improve (or optimize) illumination and/or mask used in a semiconductor manufacturing process, thereby reducing the effects of stochastic randomness on the yield of the lithographic process. In the following description, numerous details are set forth for the purpose of explanation. However, one of ordinary skill in the art will realize that the disclosed technology may be practiced without the use of these specific details. In other instances, well-known features have not been described in detail to avoid obscuring the present disclosed technology.

Some of the techniques described herein can be implemented in software instructions stored on one or more non-transitory computer-readable media, software instructions executed on a computer, or some combination of both. Some of the disclosed techniques, for example, can be implemented as part of an electronic design automation (EDA) tool. Such methods can be executed on a single computer or on networked computers.

Although the operations of the disclosed methods are described in a particular sequential order for convenient presentation, it should be understood that this manner of description encompasses rearrangements, unless a particular ordering is required by specific language set forth below. For example, operations described sequentially may in some cases be rearranged or performed concurrently. Moreover, for the sake of simplicity, the disclosed flow charts and block diagrams typically do not show the various ways in which particular methods can be used in conjunction with other methods. Additionally, the detailed description sometimes uses terms like “perform”, “generate,” “access,” and “determine” to describe the disclosed methods. Such terms are high-level abstractions of the actual operations that are performed. The actual operations that correspond to these terms will vary depending on the particular implementation and are readily discernible by one of ordinary skill in the art.

Also, as used herein, the term “design” is intended to encompass data describing an entire integrated circuit device. This term also is intended to encompass a smaller group of data describing one or more components of an entire device, however, such as a portion of an integrated circuit device. Still further, the term “design” also is intended to encompass data describing more than one micro device, such as data to be used to form multiple micro devices on a single wafer.

### Illustrative Operating Environment

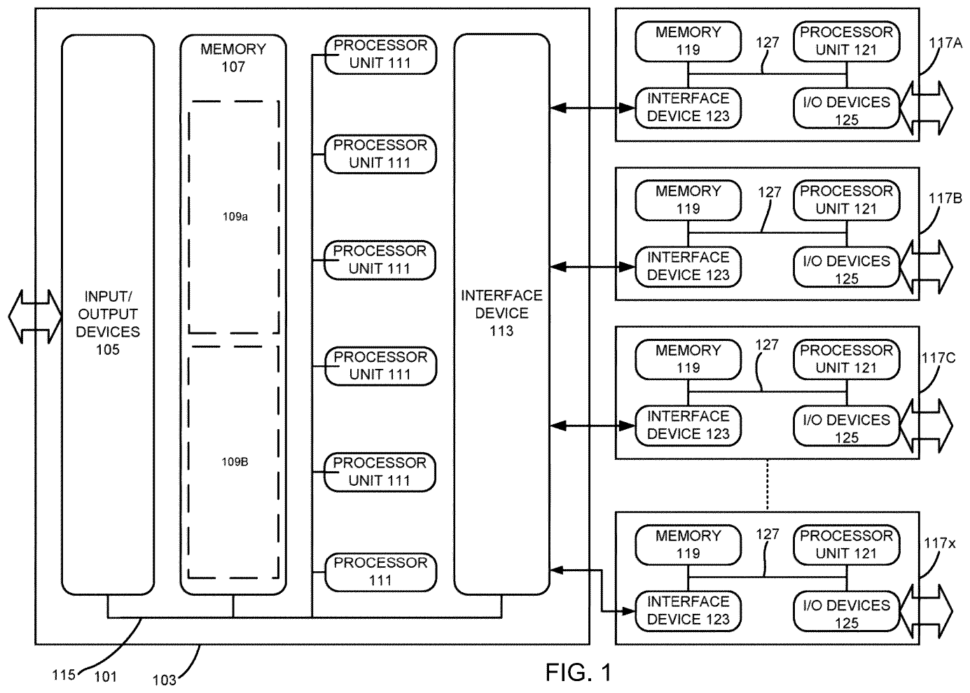

The execution of various electronic design automation processes according to embodiments of the disclosed technology may be implemented using computer-executable software instructions executed by one or more programmable computing devices. Because these embodiments of the disclosed technology may be implemented using software instructions, the components and operation of a generic programmable computer system on which various embodiments of the disclosed technology may be employed will first be described. Further, because of the complexity of some electronic design automation processes and the large size of many circuit designs, various electronic design automation tools are configured to operate on a computing system capable of simultaneously running multiple processing threads. The components and operation of a computer network having a host or master computer and one or more remote or servant computers therefore will be described with reference to FIG. 1. This operating environment is only one example of a suitable operating environment, however, and is not intended to suggest any limitation as to the scope of use or functionality of the disclosed technology.

In FIG. 1, the computer network 101 includes a master computer 103. In the illustrated example, the master computer 103 is a multi-processor computer that includes a plurality of input/output devices 105 and a memory 107. The input/output devices 105 may include any device for receiving input data from or providing output data to a user. The input devices may include, for example, a keyboard, microphone, scanner or pointing device for receiving input from a user. The output devices may then include a display monitor, speaker, printer or tactile feedback device. These devices and their connections are well known in the art, and thus will not be discussed at length here.

The memory 107 may similarly be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information.

As will be discussed in detail below, the master computer 103 runs a software application for performing one or more operations according to various examples of the disclosed technology. Accordingly, the memory 107 stores software instructions 109A that, when executed, will implement a software application for performing one or more operations, such as the operations disclosed herein. The memory 107 also stores data 109B to be used with the software application. In the illustrated embodiment, the data 109B contains process data that the software application uses to perform the operations, at least some of which may be parallel.

The master computer 103 also includes a plurality of processor units 111 and an interface device 113. The processor units 111 may be any type of processor device that can be programmed to execute the software instructions 109A, but will conventionally be a microprocessor device. For example, one or more of the processor units 111 may be a commercially generic programmable microprocessor, such as Intel® Pentium® or Xeon™ microprocessors, Advanced Micro Devices Athlon™ microprocessors or Motorola 68K/Coldfire® microprocessors. Alternately or additionally, one or more of the processor units 111 may be a custom-manufactured processor, such as a microprocessor designed to optimally perform specific types of mathematical operations. The interface device 113, the processor units 111, the memory 107 and the input/output devices 105 are connected together by a bus 115.

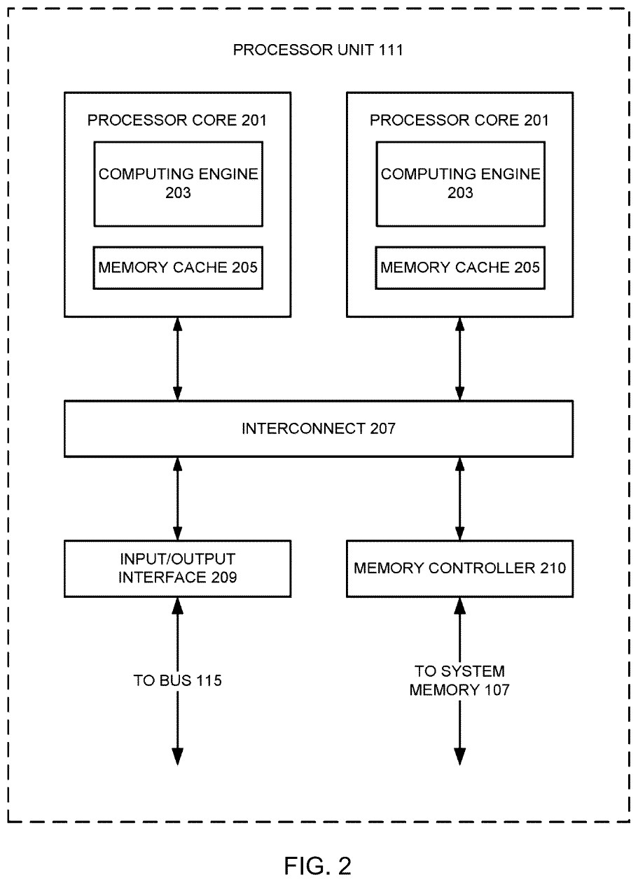

With some implementations of the disclosed technology, the master computer 103 may employ one or more processing units 111 having more than one processor core. Accordingly, FIG. 2 illustrates an example of a multi-core processor unit 111 that may be employed with various embodiments of the disclosed technology. As seen in this figure, the processor unit 111 includes a plurality of processor cores 201. Each processor core 201 includes a computing engine 203 and a memory cache 205. As known to those of ordinary skill in the art, a computing engine contains logic devices for performing various computing functions, such as fetching software instructions and then performing the actions specified in the fetched instructions. These actions may include, for example, adding, subtracting, multiplying, and comparing numbers, performing logical operations such as AND, OR, NOR and XOR, and retrieving data. Each computing engine 203 may then use its corresponding memory cache 205 to quickly store and retrieve data and/or instructions for execution.

Each processor core 201 is connected to an interconnect 207. The particular construction of the interconnect 207 may vary depending upon the architecture of the processor unit 111. With some processor cores 201, such as the Cell microprocessor created by Sony Corporation, Toshiba Corporation and IBM Corporation, the interconnect 207 may be implemented as an interconnect bus. With other processor units 111, however, such as the Opteron™ and Athlon™ dual-core processors available from Advanced Micro Devices of Sunnyvale, Calif., the interconnect 207 may be implemented as a system request interface device. In any case, the processor cores 201 communicate through the interconnect 207 with an input/output interface 209 and a memory controller 210. The input/output interface 209 provides a communication interface between the processor unit 111 and the bus 115. Similarly, the memory controller 210 controls the exchange of information between the processor unit 111 and the system memory 107. With some implementations of the disclosed technology, the processor units 111 may include additional components, such as a high-level cache memory accessible shared by the processor cores 201.

While FIG. 2 shows one illustration of a processor unit 111 that may be employed by some embodiments of the disclosed technology, it should be appreciated that this illustration is representative only, and is not intended to be limiting. Also, with some implementations, a multi-core processor unit 111 can be used in lieu of multiple, separate processor units 111. For example, rather than employing six separate processor units 111, an alternate implementation of the disclosed technology may employ a single processor unit 111 having six cores, two multi-core processor units each having three cores, a multi-core processor unit 111 with four cores together with two separate single-core processor units 111, etc.

Returning now to FIG. 1, the interface device 113 allows the master computer 103 to communicate with the servant computers 117A, 117B, 117C . . . 117x through a communication interface. The communication interface may be any suitable type of interface including, for example, a conventional wired network connection or an optically transmissive wired network connection. The communication interface may also be a wireless connection, such as a wireless optical connection, a radio frequency connection, an infrared connection, or even an acoustic connection. The interface device 113 translates data and control signals from the master computer 103 and each of the servant computers 117 into network messages according to one or more communication protocols, such as the transmission control protocol (TCP), the user datagram protocol (UDP), and the Internet protocol (IP). These and other conventional communication protocols are well known in the art, and thus will not be discussed here in more detail.

Each servant computer 117 may include a memory 119, a processor unit 121, an interface device 123, and, optionally, one more input/output devices 125 connected together by a system bus 127. As with the master computer 103, the optional input/output devices 125 for the servant computers 117 may include any conventional input or output devices, such as keyboards, pointing devices, microphones, display monitors, speakers, and printers. Similarly, the processor units 121 may be any type of conventional or custom-manufactured programmable processor device. For example, one or more of the processor units 121 may be commercially generic programmable microprocessors, such as Intel® Pentium® or Xeon™ microprocessors, Advanced Micro Devices Athlon™ microprocessors or Motorola 68K/Coldfire® microprocessors. Alternately, one or more of the processor units 121 may be custom-manufactured processors, such as microprocessors designed to optimally perform specific types of mathematical operations. Still further, one or more of the processor units 121 may have more than one core, as described with reference to FIG. 2 above. For example, with some implementations of the disclosed technology, one or more of the processor units 121 may be a Cell processor. The memory 119 then may be implemented using any combination of the computer readable media discussed above. Like the interface device 113, the interface devices 123 allow the servant computers 117 to communicate with the master computer 103 over the communication interface.

In the illustrated example, the master computer 103 is a multi-processor unit computer with multiple processor units 111, while each servant computer 117 has a single processor unit 121. It should be noted, however, that alternate implementations of the disclosed technology may employ a master computer having single processor unit 111. Further, one or more of the servant computers 117 may have multiple processor units 121, depending upon their intended use, as previously discussed. Also, while only a single interface device 113 or 123 is illustrated for both the master computer 103 and the servant computers, it should be noted that, with alternate embodiments of the disclosed technology, either the computer 103, one or more of the servant computers 117, or some combination of both may use two or more different interface devices 113 or 123 for communicating over multiple communication interfaces.

With various examples of the disclosed technology, the master computer 103 may be connected to one or more external data storage devices. These external data storage devices may be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information. According to some implementations of the disclosed technology, one or more of the servant computers 117 may alternately or additionally be connected to one or more external data storage devices. Typically, these external data storage devices will include data storage devices that also are connected to the master computer 103, but they also may be different from any data storage devices accessible by the master computer 103.

It also should be appreciated that the description of the computer network illustrated in FIG. 1 and FIG. 2 is provided as an example only, and it not intended to suggest any limitation as to the scope of use or functionality of alternate embodiments of the disclosed technology.

### Stochastic Modeling

Lithography may comprise patterning layers for semiconductor dies. As discussed above, random stochastic phenomena may affect lithography, particularly EUV lithography, resulting in defects in the semiconductor dies. As discussed in the background, one solution to determine the effect of the random stochastic phenomena is to perform Monte Carlo simulations. In particular, potentially millions of different Monte Carlo simulations, with random seeds encoding the locations where the individual photons are absorbed in the resist film, may be run. The random seeds serve as starting points for random number generators to simulate small random variations. Millions of the simulations, which are performed for a large portion of the layer (and not merely for the critical portions), result in success or failure, thereby generating a distribution of success or failure. This procedure to perform millions of simulations is very computationally expensive.

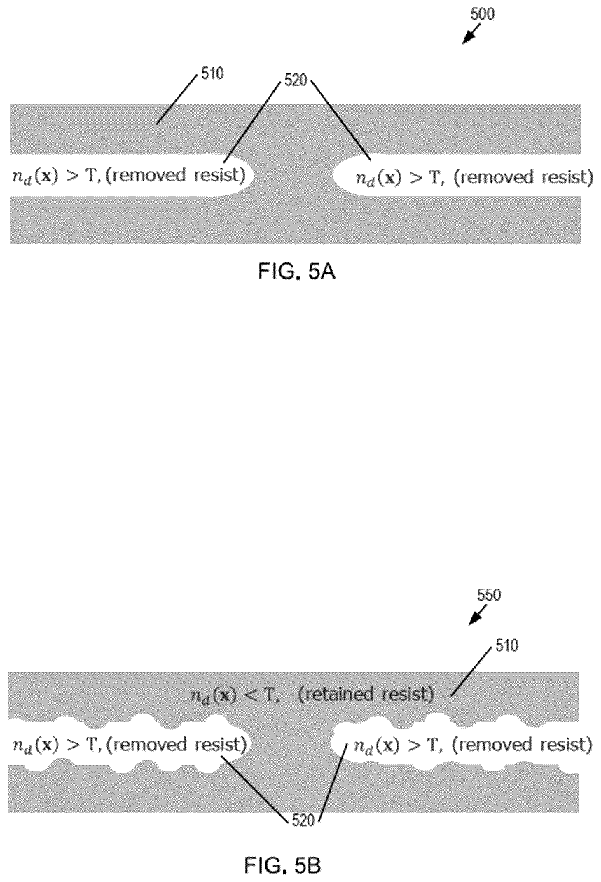

In contrast, in some embodiments, rather than running Monte Carlo simulations, a stochastic model is generated. The stochastic model may model one or more stochastic phenomena including any one, any combination, or all of: photon shot noise (e.g., random absorbed photon density); stochastic phenomena in the resist process or other chemical stochastic process; stochastic phenomena in the resist development (e.g., for a variety of resist processes, including using chemically amplified resists (CAR) or non-CAR, such as MOx). As discussed in further detail below, it may be assumed that the number of photons absorbed in any pre-specified volume in the photoresist during the exposure follows a Poisson distribution. The stochastic randomness of the locations as to where the photons are absorbed may comprise one manner of addressing stochastic phenomena, such as discussed with regard to FIG. 5B below. Likewise, other stochastic phenomena may be considered, such as stochastic phenomena after the photons are absorbed. As one example, stochastic phenomena related to one or more chemical processes, such as chemical stochastic phenomena including chemical noise (e.g., secondary electron diffusion noise in EUV resist, PAGs activation, acid diffusion/reaction), may likewise be considered by the stochastic model. As another example, stochastic phenomena in the resist development may also be considered by the stochastic model.

The stochastic model, which may comprise a continuous random field model, may be defined with its distribution parameters calculated from the known image intensity in resist and one or more parameters of the resist process. The stochastic model may thus receive one or more inputs (e.g., (1) light exposure parameter(s); (2) resist model parameter(s); and (3) success/failure criteria) and generate one or more outputs indicating the probability of success or failure of at least a part of the layer. For example, the stochastic model may determine the success or failure of critical sections of the layer identified as particularly susceptible to failure. In this way, the stochastic model may: (i) provide a computationally efficient way to calculate the success or failure probability of the outcome of the lithographic process with respect to the stochastic randomness in exposure and the resist process; and/or (ii) enable the improvement (or optimization) of the illumination (e.g., source) and/or the mask (e.g., with regard to source-mask optimization (SMO) or optical proximity correction (OPC) algorithms) in order to reduce or mitigate the effects of stochastic randomness on the yield of the lithographic process. Examples of lithographic processes are disclosed in US Patent Application Publication No. 2015/0067628 A1 and US Patent Application Publication No. 2019/0102501 A1, both of which are incorporated by reference in their entirety.

Thus, the stochastic model may efficiently identify certain critical sections prone to failure (based on the determined probability of success/failure) in order to modify one or both of the intensity (or other light exposure parameter) or the resist (such as the pattern in the layout design) to reduce the possibility of failure. Further, the probability generated by the stochastic model may be included as a factor (along with one or more other factors) in a lithographic cost function for the source and/or mask optimization algorithms, as discussed in U.S. Pat. No. 11,061,373 entitled “Method and System for Calculating Probability of Success or Failure for a Lithographic Process Due to Stochastic Variations of the Lithographic Process”, incorporated by reference herein in its entirety.

Stochastic models used in several simulation algorithms (e.g., the OPC algorithm) may simulate and quantify the variability of the resist patterns, such as treating these resist patterns as two-dimensional features, and may essentially assume an averaged outcome across the resist film (e.g., from the top to the bottom of the resist film). However, the SEM metrology inspection of many typical lithographic patterns patterned in resist using EUV lithography shows that the three-dimensional (3D) profile of the post-development resist features may be essential for the defect formation, such as a resist top surface roughness “TSR”, resist scumming, stochastic sidelobe printability in the top surface of the resist, thickness loss, development rate variation, and the like. The 3D profiles may increase sensitivity with less sampling for a way to calibrate the stochastic model. Further, 3D stochastic resist effects may become worse for smaller features, which thereby may necessitate estimating 3D stochastic resist effects reliably. It is, therefore, advantageous to use the stochastic model to predict and to quantify the variability of the resist features in all three dimensions, such as the stochastic variability of the thickness of the resist film.

3D simulations may be difficult to perform, particularly for 3D modeling for resist features. 3D simulations, such as disclosed in Luke T. Long, Andrew R. Neureuther, and Patrick P. Naulleau “Three-dimensional modeling of EUV photoresist using the multivariate Poisson propagation model,” Journal of Micro/Nanopatterning, Materials, and Metrology 20(3), 034601, 2 Jul. 2021, https://doi.org/10.1117/1.JMM.20.3.034601), are possible; however, these methodologies may not be practical for a large set of patterns needed to calibrate the stochastic model or to verify the process performance for a large variety of patterns.

In this regard, a method of using the stochastic model according to some embodiments of the disclosed technology is disclosed, which may predict and mitigate undesired 3D stochastic effects (e.g., any one, any combination, or all of resist scumming, stochastic sidelobe printability in the top surface of the resist, thickness loss, development rate variation, and the like). Further, although the lithography process may essentially address fabrication of 2D layers, the stochastic 3D effects in resist may affect the etching outcome, and in turn affect the final yield. Therefore, use of the stochastic model according to some embodiments of the disclosed technology may be extended to modeling 3D stochastic variability of the etching process. The stochastic model according to some embodiments of the disclosed technology may also be used in lithography processes targeting a fabrication of 3D features (e.g., 3D NAND).

Further, the method of using the stochastic model according to some embodiments of the disclosed technology may be used to calibrate a stochastic model using traditional stochastic metrics reflecting the 2D stochastic variability of the EUV lithography result (e.g., line edge roughness “LER”, line width roughness “LWR”, local CD uniformity “LCDU”, and the like), followed by using such calibrated stochastic model to predict (and potentially mitigate) the essentially 3D manifestations of EUV lithography stochastic variability (e.g., any one, any combination, or all of resist top surface roughness “TSR”, resist scumming, stochastic sidelobe printability in the top surface of the resist, thickness loss, development rate variation, and the like).

In some embodiments, the stochastic model, which may comprise a continuous random field model, may: receive one or more inputs (e.g., any one, any combination, or all of: (1) light exposure parameter(s); (2) resist model parameter(s); and (3) success/failure criteria); model the stochastic randomness (e.g., stochastic variability) for a plurality of levels; analyze the stochastic randomness modeled for each of the plurality of levels; and generate one or more outputs indicative a stochastic variability in a 3D area associated one or more aspects of the lithography process.

The stochastic model (e.g., the random filed model) may model 3D stochastic randomness by modeling the stochastic randomness for a plurality of levels (e.g., a plurality of layers, or a plurality of planes). In some embodiments, as discussed above, the stochastic model may model stochastic randomness in the one or both of exposure or resist process using one or both of the at least one light exposure parameter or the at least one resist model parameter. Each of the plurality of levels may be discrete from one another in a z-direction. In some embodiments, the plane corresponding to a substrate surface on which the resist film is formed may be referred to as an x-y plane, and the z-direction may be a perpendicular to the substrate surface. The z-direction may correspond to the thickness direction of the resist. Each of the plurality of levels may correspond to the x-y plane. The stochastic model may, respectively, model the stochastic randomness for each level of a plurality of discrete levels. By modeling the stochastic randomness for the plurality of discrete levels, 3D stochastic randomness may be modeled more accurately in three dimensions. In some embodiments, the modeled stochastic randomness for the plurality of discrete levels may then be used as a basis for modeling the stochastic randomness across 3D space (e.g., in the z-direction). As one example, estimation, such as interpolation, may be used to model the stochastic randomness across 3D space, as discussed in more detail below.

Various types of stochastic randomness may be modeled. For example, the stochastic randomness may include a probability distribution function of deprotection concentration indicative of success or failure probability of the lithographic process or a printed area distribution function (e.g., the printed area metric indicative of the likelihood of printing within the printed area or the variance of printing within the printed area). In particular, the calculation or the modeling of the various stochastic randomness for each of the plurality of levels may be performed using the stochastic model and the methods described in U.S. Pat. No. 11,061,373, entitled “Method and System for Calculating Probability of Success or Failure for a Lithographic Process Due to Stochastic Variations of the Lithographic Process” and U.S. Pat. No. 11,270,054, entitled “Method and System for Calculating Printed Area Metric Indicative of Stochastic Variations of the Lithographic Process” incorporated by reference herein in their entirety.

In some embodiments, a number of levels, such as pre-defined number, of levels may define the 3D space in the z-direction. The number of such levels and their positions may be determined based on the requirements and definitions of the 3D stochastic variability phenomena targeted by the stochastic model. For instance, the basic stochastic model may use just a single sampling plane parallel to the substrate and positioned inside the resist film. The more involved stochastic model, targeting at quantification of the stochastic perturbations of the top surface of the developed resist film, may also use the second sampling plane positioned closer to the top surface of the resist film. If the stochastic model targets the even more detailed quantification of stochastic variability, it may use multiple sampling planes inside the resist film, or even a 3D spatial grid sampling the resist film, with the X/Y/Z grid sizes in few nanometers (e.g. 1, 2 or 3 nm). Another option may be to use 1D or 2D grid sampling of the resist in the direction perpendicular to the substrate, to capture the stochastic randomness (e.g., stochastic variability) of the resist process across the resist film at a pre-defined X-Y position or at a certain plane cutting the resist film perpendicularly to the substrate.

In some embodiments, the stochastic model may model the stochastic randomness of one or more variables or variable parameters in the z-direction (e.g., variable across the plurality of levels). For example, the stochastic model may model stochastic variability, such as modeling the variability between independent stochastic trials. In this regard, the stochastic model may model the stochastic randomness of one or both of the at least one light exposure parameter or the at least one resist model parameter. In this regard, the stochastic model may model the stochastic randomness by using the variable parameter. For example, in modeling the stochastic randomness for each of the plurality of levels, the stochastic model may use a corresponding value of the variable parameter for each of the plurality of levels, such that the stochastic model may use different values of the variable parameter for each of the plurality of levels. In other words, a value of the variable parameter used in modeling the stochastic randomness for a first level of the plurality of levels may be different from a value of the variable parameter used in modeling the stochastic randomness for a second level of the plurality of levels. Throughout the specification, the terms such as “first”, “second” and the like may be used in describing various elements, but the elements should not be limited by the terms. These terms are only for distinguishing the elements from other elements, and the nature or the sequence or order of the elements should not be limited by the terms unless a particular ordering is required by specific language set forth below. For example, the value of the at least one variable parameter at a top level may be different from the value of the at least one variable parameter at a lower level (e.g., with respect to the z-direction, such as a bottom level).

In some embodiments, the stochastic model may model the stochastic randomness from top to bottom. The development step in the resist process may proceed with the removal of the resist material beginning from the top surface of the resist film. The random variability (i.e., stochastic randomness) in the exposure, post exposure bake, and the development steps of the process, described above, may result in the variability of one or both of the intended openings in the resist film and the top surface of the resist film. The stochastic model may address the variability of the top surface of the resist film after the development, for instance to identify the locations where undesired openings in the developed resist may form, with a certain probability deemed to be too high.

In some embodiments, the variable parameter may include a variable image intensity in the resist, which may be one of the light exposure parameters. The image intensity in the resist may be variable in the z-direction (e.g., across the plurality of the discrete levels) such that the image intensity may have different values across the plurality of discrete levels. For example, an image intensity near a top surface of the resist may be different from an image intensity near a bottom surface of the resist. In modeling the stochastic randomness for each of the plurality of levels, the stochastic model may use an image intensity corresponding to a respective level for which the stochastic model models the stochastic randomness. The image intensity used in modeling the stochastic randomness for a first level of the plurality of levels may be different from the image intensity used in modeling the stochastic randomness for a second level of the plurality of levels.

In some embodiments, the variable parameter may include a variable resist removal threshold, which may be one of the resist model parameters. The resist removal threshold may be variable in the z-direction (e.g., across the plurality of the discrete levels) such that the resist removal threshold may have different values across the plurality of discrete levels. In other words, a resist removal threshold for a level near a top surface of the resist may differ from a resist removal threshold for a level near a bottom surface of the resist. For example, values of the variable resist removal threshold may decrease from the bottom surface to the top surface of the resist. In modeling the stochastic randomness for each of the plurality of levels, the stochastic model may use resist removal threshold value corresponding to a level for which the stochastic model models the stochastic randomness. A resist removal threshold value used in modeling the stochastic randomness for a first level of the plurality of levels may be different from a resist removal threshold value used in modeling the stochastic randomness for a second level of the plurality of levels. For example, a resist removal threshold used in modeling the stochastic randomness for a level near a top surface of the resist may be lower than a resist removal threshold used in modeling the stochastic randomness for a level near a bottom surface of the resist.

Modeling the stochastic randomness by using different values of the variable parameter for each of the plurality of discrete levels (instead of using a vertically static parameter that may be consistent across the plurality of levels, e.g., consistent in the z-direction) may increase the accuracy in modeling of the stochastic randomness in 3-dimensions in accounting for the top-to-bottom nature of the development process.

After modeling the stochastic randomness for each of the plurality of discrete levels, the modeled values each indicative the stochastic randomness (e.g., 2-dimensional distribution), modeled values for the plurality of discrete levels may be analyzed in combination in order to determine the stochastic randomness in 3-dimensions. As one example, the modeled values each indicative the stochastic randomness, for some or each of the plurality of levels, may be estimated (e.g., interpolated) in order to generate a 3-dimentional distribution of the stochastic randomness. In particular, if the modeled values are 2-dimentional distributions for the stochastic randomness for specific levels in the z-direction, for example, level 1 and level 2, the 2-dimensional distribution for the stochastic randomness for an intermediate level between level 1 and level 2 may be obtained by interpolating two independent 2-dimentional distributions for level 1 and level 2.

One or more types of interpolation may be used, such as any one, any combination, or all of: piecewise constant interpolation; linear interpolation; polynomial interpolation; spline interpolation; mimetic interpolation; or other methods that are known to those skilled in the art may be used

By interpolating the values modeled for each of the plurality of the levels discrete from one another in the z-direction, the application of the stochastic model may be effectively extended to 3D aspects.

After interpolating the stochastic randomness modeled, indications of stochastic variability in one or more areas of interest may be calculated based on the 3-dimentional distribution of the stochastic randomness. The one or more areas of interest may include a z-direction aspect. In other words, the one or more area of interest may include any one, any combination, or all of a 3D area of interest (e.g., a volume of interest), a plane of interest that is vertical to the x-y plane, or a line of interest that is vertical to the x-y plane. Various indications of the stochastic variability may be calculated as described in U.S. Pat. No. 11,061,373, entitled “Method and System for Calculating Probability of Success or Failure for a Lithographic Process Due to Stochastic Variations of the Lithographic Process” and U.S. Pat. No. 11,270,054, entitled “Method and System for Calculating Printed Area Metric Indicative of Stochastic Variations of the Lithographic Process”, each incorporated by reference herein in their entirety.

In some embodiments, the indications of the stochastic variability may include a success or a failure probability of the lithographic process. The indications of the success or the failure probability of the lithographic process may be calculated based on the success or failure criteria. The indications of stochastic variability in one or more areas may also include one or more defined moments for a printed area distribution associated with the printed area that are indicative of one or more aspects associated with printing, such as any one, any combination, or all of a top surface roughness (“TSR”), a power spectral density (“PSD”), an average printed volume relating to printing due to the stochastic randomness that are not supposed to be printed relating to printing due to the stochastic randomness that are not supposed to be printed in a user-defined volume of the interest, a 3D sidelobe printing in the volume of interest, a standard deviation of a printed volume relating to variation in printing due to the stochastic randomness that are not supposed to be printed in a volume of interest, variability of a via in the resist, which may be considered indication of the success or the failure probability of the lithographic process.

Various stochastic models and methods to model the stochastic randomness for each of the plurality of discrete levels are contemplated, including without limitation a continuous random field model, a Gaussian random field model, and a multivariate normal distribution model. Other stochastic models are contemplated. Further, various calculations are contemplated to determine the indications of stochastic variability for the defined area of interest, as described below.

With regard to the continuous random field model, a final outcome of the random stochastic processes associated with the lithographic process, including random stochastic processed related to any one, any combination or all of the resist exposure, resist processing and resist development, may be described as a certain random field. As one example, a random field is a term for a stochastic process with at least one restriction on its index set. Using the continuous random field model, the distribution parameters of the random field may be efficiently calculated from the known intensity of the image in resist and the parameters of the resist process. As one example, the continuous random field model may be used to consider one or more stochastic phenomena (e.g., random absorbed photon density, chemical stochastic phenomena, or resist development) and/or model complicating factors, such as one, any combination, or all of: (1) resist saturation effects related to the resist may be considered by the stochastic model, including with regard to photoacid generators (PAGs), other acids/quenchers, or the like for the resist; (2) development/3D effects; or (3) reaction-diffusion non-linearity during post exposure bake (PEB). Other model complicating factors are contemplated as well.

With regard to the Gaussian random field model, the Central Limit Theorem (CLT) may be used to accurately approximate the concentration of deprotection resulting from the resist exposure by a Gaussian random field (GRF), which is a type of random field involving Gaussian probability density functions of the variables. For example, the GRF model may be used when considering certain types of stochastic phenomena, such as random absorbed photon density (without potentially considering resist saturation effects). Using the Gaussian random field model, one or more parameters of the GRF (e.g., the mean and/or the covariance function) may be calculated from the known intensity of the image in resist and the parameters of the resist process. In particular, the GRF model may be defined by the mean function and a two-point covariance function.

With regard to the multivariate normal (MVN) distribution model, various critical portions of the layer, such as a finite set of observation points, may be subject to analysis. As such, the outcome of the resist exposure process may be quantified as the set of values of deprotection concentration sampled at the finite set of observation points (also referred to as “sampling points” or “pixels” or “voxels”) in the resist film. Application of CLT to deprotection concentration sampled at these sampling points may yield that the random vector composed of the values of deprotection concentrations at these sampling points is distributed as a multivariate normal (MVN) distribution, which is a generalization of the one-dimensional normal distribution to higher dimensions. Using the MVN distribution model, one or more parameters (e.g., the mean vector and/or the covariance matrix) of this MVN may be calculated from the known intensity of the image in resist and the parameters of the resist process. In particular, the MVN distribution model may be defined by the mean vector and a symmetric positively semi-definite covariance matrix, which may be determined by performing a calibration based on a set of experimental measurements.

Further, as discussed above, separate from generating the stochastic model representing the deprotection concentration, at least a part of the lithographic process, such as one or more lithographically significant events, may be defined in terms of success or failure criteria of the lithographic process. In some embodiments, the lithographically significant events may be defined as a set of certain equality or inequality conditions in terms of any values, derivatives or their functionals, derived from the parameters of the stochastic model, such as the random field model, described above.

In particular, for a respective lithographic event, success and/or failure may be defined based on a determined outcome of the respective lithographic event. Example determined outcomes of lithographic events include any one, any combination, or all of: determination as to whether pinching or bridging has occurred; determination as to whether the lithographic process results in the complete removal of the resist material in a defined area; determination as to whether the lithographic process results in the complete retention of the resist material inside another defined area). Further, the outcome of the lithographic events, which may define success or failure, may be analyzed in one of several ways. For example, the outcome of the lithographic event may be determined using a cutline (or other shaped defined geometric shape. As another example; the outcome of the lithographic event may be dependent on defined sets, such as a defined isolation set(s) in which success is defined as the complete retention of the resist material therein and/or a defined integrity set(s) in which success is defined as the complete removal of the resist material therein; etc.

In this way, determination of the outcome of the lithographic events may comprise determining resist removal (such as complete resist removal) at one or more user-defined areas and/or resist retaining (such as complete retention of the resist material at one or more other user-defined areas. In particular, the success or failure criteria may be defined as a set of inequalities expressing a complete removal of the resist material at certain user-defined areas, V_{D}, in the resist, and a complete retention of the resist material at certain other user-defined areas, V_{P}. As discussed above, one type of stochastic model comprises a Gaussian random field model. In such a model, the inequalities may state that the deprotection concentration exceeds the resist removal threshold everywhere in V_{D} (the user-defined areas for complete removal of the resist material) and the same deprotection concentration is less than the resist removal threshold everywhere in V_{P} (the user-defined areas for complete retention of the resist material).

One success criterion comprises gauge critical dimension (CD)-based success criterion. In particular, one definition of the lithographically significant event, which constitutes a success of the lithographic process, is based on using a cutline (e.g., a gauge or other defined geometric shape) CD-based success criterion. In such a methodology, the cutline (e.g., the gauge or other defined geometric shape) is placed on a certain part of the pattern, such as a critically important part of the pattern, with the success or failure dependent on the removal or retention of the resist material at one or more defined points (such as one or more user-defined points) along the cutline. Various cutlines are contemplated, including a single line that cuts across the critically important part of the pattern. Illustrations and the verification of success probabilities computed using the gauge CD-based success criterion against the Monte Carlo simulations are discussed in more detail below.

Another definition of a lithographically significant event (typically constituting a failure of the lithographic process) is based on using the cutline (e.g., gauge or other defined geometric shape) as a detector of pinching or bridging. In such an instance, the cutline (e.g., gauge or other defined geometric shape) is placed at the expected location of the pinching or bridging, and the complete removal or complete retention of the resist along at least a part of the cutline (such as along the entire gauge) is used as a criterion for pinching/bridging occurring at the location of the gauge. Illustrations and the verification of success probabilities computed using the gauge based pinching or bridging failure criterion against the Monte Carlo simulations are discussed in more detail below.

Still another definition of the lithographically significant event is based on one or both of integrity set(s) or isolation set(s). For example, the integrity set(s) and/or isolation set(s) may be defined by applying, respectively, negative/positive bias to the target polygons and taking, respectively, the interior/exterior of the resulting biased polygons. After the integrity/isolation sets are defined, the success criterion of the lithographic process may be defined as a certain defined measure of (e.g., such as a complete) removal of the resist material inside the integrity set(s) and/or as another defined measure of (e.g., such as the complete) retention of the resist material inside the isolation set(s).

As discussed above, after generating the stochastic model and defining the success and/or failure criteria, the success and/or failure probability may be calculated. The calculation of the success and/or failure probability may generate one or more types of probability functions, such as a probability density function or a cumulative distribution function. For example, using the definition of success or failure defined above and using the knowledge of the distribution parameters of the stochastic model (e.g., the distribution parameters of the continuous random field model described above, for instance), one or more types of distribution functions, such as the probability density function or the cumulative distribution function may be generated to calculate the probability of interest. A probability density function, also known as a density of a continuous random variable, is a function whose value at any given sample (or point) in the sample space (the set of possible values taken by the random variable) multiplied by the measure (e.g., a length or a volume) of a small area surrounding this sample (e.g., point) is equal to the probability of the random variable assuming its values within this small area. The cumulative distribution function of a real-valued random variable, or simply the distribution function of X, evaluated at x, is the probability that X will take a value less than or equal to x.

Thus, various methodologies may be used to calculate the probability of interest. In some embodiments, a multivariate normal distribution cumulative distribution function (MVNCDF) may be used. In particular, MVNCDF, which may be considered an extension of a cumulative distribution function to the multidimensional case, may be used to calculate the success or failure probabilities of lithographically significant events defined as described above. Efficient algorithms for calculating MVNCDF may be found in both of the following, incorporated by reference herein in their entirety: Alan Genz and Frank Bretz. Computation of Multivariate Normal and t Probabilities. Springer (2009). ISBN 978-3-642-01689-9; Botev, Z. I., “The normal law under linear restrictions: simulation and estimation via minimax tilting”, Journal of the Royal Statistical Society, Series B (2016), arXiv:1603.04166.

In other embodiments, a Mahalanobis distance and the probability of the statistical interval bound by the Mahalanobis distance may be used. In particular, instead of calculating the probability using the MVN distribution model using MVNCDF (as described above), one may calculate the Mahalanobis distance, which is a measure of the distance between a point P and a distribution D, associated with the MVN distribution model. This Mahalanobis distance may be calculated between the MVN distribution and the deterministic (non-random) state (e.g., “a point”) of the system corresponding to the successful lithographic outcome, as described above (e.g., where the definition of success or failure is a zero deprotection concentration for the sampling points, where the resist is to be retained, and a certain user-defined value of deprotection concentration exceeding a deprotection threshold for the sampling points, where the resist is to be removed). Although the Mahalanobis distance calculated in this manner does not directly correlate to the probability of the successful outcome, the Mahalanobis distance may be indicative of the probability. For example, the higher/lower values of this Mahalanobis distance may signal lower/higher probabilities of the success or failure. Thus, the Mahalanobis distance may be used as a metric indicating the improvement of the success probability. Furthermore, the value of the Mahalanobis distance may be used to provide an estimate of such probability using the inverse of the quantile function (which may specify the value of the random variable such that the probability of the variable being less than or equal to that value equals the given probability) for the χ² distribution with the appropriate number (e.g., “k”) of degrees of freedom (e.g., the distribution of a sum of the squares of “k” independent standard normal random variables). Using the Mahalanobis distance and the inverse of the quantile of the chi-squared distribution is less computationally expensive than other calculations, such as the calculation of MVNCDF.

In still other embodiments, Machine Learning (ML) methodologies may be used to quickly estimate the success or failure probability. For example, various regression techniques practiced in ML may be applied to provide a computationally efficient method to calculate the success/failure probability based on a continuous random field model (as discussed above), the definition of the success/failure criteria (as discussed above) and ML training datasets. The ML training datasets may be multiple exemplar combinations of relevant instances of inputs, including different stochastic models (e.g., continuous random field model; Gaussian random field model; MVN distribution model) and of different definitions of success/failure criteria (e.g., in terms of resist removal/retention, such as gauge CD-based success criterion, gauge-based pinching or bridging criterion, integrity/isolation sets criterion) along with the corresponding probabilities (outputs). For instance, for the MVN model, an artificial neural network (which may comprise a framework for the machine learning methodology) or a support vector machine (which may comprise a set of related supervised learning methods used for classification and regression) may be used to build a regression model using training sets generated using one of the implementations of the MVNCDF function. After such regression model has been trained, it may be used to perform the probability calculation instead of the MVNCDF function, discussed above, potentially resulting in faster computational performance.

In yet other embodiments, Rice's formula may be used to quickly estimate the average number of defects or the probability of a defect. Rice's formula, which gives the average number of times an ergodic stationary process considered within a certain interval crosses a fixed level u, thus providing an exact expression for the expectation (e.g., a mean or an average) of the number of up-crossings above a given threshold for a continuous random process. As discussed above, the random process may comprise a continuous random field or a Gaussian random field representing the deprotection concentration and sampled along a certain curve. Such curve, for instance, may be selected to be a straight line parallel to a line in a periodic lines and spaces array, and positioned at the middle of this line. The number of up-crossings of the deprotection concentration above the deprotection threshold may provide the approximation of the number of pinching defects across this line. Strictly speaking, such count is a count of the number of times the midpoint of the line is deprotected, which merely approximates the number of pinchings. Nevertheless, lithography errors may be based on the estimation of the lines and spaces failure rate or the lines and spaces defect densities based on counting the number of deprotections of the line or a space midpoint.

One manner of using Rice's formula to estimate the average number of defects may be based on the “pixel not OK” (pixNOK) metric, which may represent the failure probability according to the following: pixNOK=Σpixels in failure/Σpixels inspected. In the case of the pixNOK metric (or a number of defects), the random process in question may comprise the value of deprotection concentration along the middle of the line (of a periodic LS array). In the framework of a simplistic resist model, this particular process is a stationary Gaussian process with a constant mean and a constant variance. Its realizations (e.g., sampling paths) are smooth functions, because they result from convolutions of absorbed photon density (e.g., delta functions centered at the sites of photon absorptions) and a smooth simplistic resist model kernel. Such convolution is as smooth as the kernel of the simplistic model, which is typically a Gaussian function.

In such a situation, Rice's formula for a Gaussian process (not necessarily stationary) with a zero mean and a constant unit variance (not restrictive requirements) is as follows:

$$𝔼 \{ {N}_{u}^{+} ( 0 , T ) \} = \frac{{e}^{- {u}^{2 / 2}}}{2 π} {\int }_{0}^{T} {λ}_{t}^{1 / 2} d t \qquad ( 1 )$$

where λₜ is the variance of the process derivative, f′(t). The variance of the process derivative with regard to process of interest (e.g., deprotection concentration sampled along the middle of the line) may be calculated from the known image and the kernel of the simplistic resist model in the same manner as the variance of deprotection itself is calculated. In particular, such a derivative of the process is equal to a convolution of absorbed photon density (e.g., delta functions centered at the sites of photon absorptions) and a derivative of the simplistic resist model kernel. The variance of the process derivative may thus be calculated from the same variance formula as the model establishes for the process itself, with the kernel replaced by its derivative along the middle of the line. In this way, the expectation of the number of defects may be calculated using Rice's formula, including the random processes sampled along the non-periodic lines and spaces, bending lines and spaces, sampled across the feature (e.g. across the line or a space), or sampled across a via/contact hole diameter.

Thus, any one, any combination, or all of the following may improve analysis (including significant reduction in runtime) of potential errors in the lithographic process due to stochastic phenomena including: (a) using an ad hoc statistical model of the stochastic phenomena in the exposure and the resist process (e.g., the continuous random field model, the Gaussian random field model, or the MVN distribution model); (b) defining the success/failure of lithographic events in ways allowing the use of probability distribution functions of the statistical models to calculate the respective probabilities; and (c) calculating the success/failure probabilities analytically or semi-analytically, based on the model and the events definitions in (a) and (b).

In this way, the methodology makes it practical to calculate the success/failure probability in one, some, or every iteration of the multiple iterations of the SMO, OPC or verification algorithms for the entire die of the integrated circuit. This is unlike typical analysis methodologies, such as based on Monte Carlo, that make the use of experimental exposures and measurements in multiple iterations of the mask preparation flow impractical. Rather, calculating the success/failure probability for the entire chip/die within a reasonable time allows quick verification of the OPC/SMO solutions and to calculate the OPC/SMO solutions, thereby reducing the probability of stochastic failure and improving the yield, particularly in the EUV lithography.

In one implementation of OPC, the mask pattern is modified (such as iteratively modified) in order to produce the mask pattern yielding the optimal process result with regard to a certain criterion (e.g., the least edge placement error or the least failure probability). An example of OPC is disclosed in US Patent Application Publication No. 2016/0292348, incorporated by reference herein in its entirety.

In one implementation, in SMO, the mask pattern, illumination mode and potentially exposure dose are modified (such as iteratively modified) to produce the optimal process result (e.g., the least edge placement error or the least failure probability). An example of SMO is disclosed in US Patent Application Publication No. 2015/0067628, incorporated by reference herein in its entirety.

The methodology disclosed further enables substantial reduction in the prohibitively significant run time requirements needed for typical analytical methodologies, such as Monte Carlo trials. The methodology disclosed herein, such as using a MVNCDF based methodology, may produce comparable results to Monte Carlo trials for the success/failure probabilities calculated. For example, a success/failure probability of 5.0×10⁻⁶ or less may require 1 to 2 million Monte Carlo simulations, and may take on the order of 5 hours of run time (using a typical modern CPU). In contrast, calculating the same probability using the MVNCDF methodology as disclosed herein may take approximately from 10 to 50 seconds for the same test cases, demonstrating a reduction of the runtime by a factor of 360 to 1800. In this way, the methodology disclosed herein may result in a very significant reduction in runtimes over prior typical methodologies.

As discussed in the background, one solution to analyze or mitigate the SRAF or sidelobe printing is to analyze SEM measurements results to assess the frequency of the SRAF or sidelobe printing in multiple experimental trials. However, the experimental measurements of multiple repeated identical exposures are practical only for a small subset of patterns of the integrated circuit layer.

In some embodiments, rather than running Monte Carlo simulations or the like, a printed area metric based on an analytical solution (rather than a simulated solution) is generated. The analytical printed area metric comprises one or more defined moments for a printed area distribution associated with the printed area that are indicative of one or more aspects associated with printing (e.g., the likelihood of printing within the printed area; variance of printing within the printed area; skewness of the printed area; kurtosis of the printed area; etc.) due to stochastic randomness in one or both of exposure or resist process. In particular, the printed area may be considered the random variable from a stochastic standpoint. As such, different moments may be calculated for the printed area distribution associated with the printed area.

Various ways are contemplated to calculate the moments for the printed area distribution. As discussed in more detail below, the moments for the printed area distribution may be calculated without direct knowledge of the printed area distribution. In one or some embodiments, a distribution (such as cumulative distribution function (CDF)) associated with deprotection of resist for the printed area may be used to calculate the moments for the printed area distribution. In this way, knowledge of the distribution associated with deprotection enable the calculation of the moments for the printed area distribution without the need for deriving the CDF for the printed area distribution. As discussed further below, the first moment (e.g., the first raw moment) and the second moment (e.g., the second central moment) may be calculated. Higher order moments, such as the third moment (skewness), fourth moment (kurtosis), and other higher moments, are contemplated as well (e.g., in a calculation of the expected value of the resistance of a via, assuming that the resistance of the via satisfies the Pouillet's law where resistance is proportional to the via material resistivity and the length of the via and is inversely proportional its cross-section area). Alternatively, the moments may be calculated directly from the printed area distribution.

As one example, a first moment, indicative of the average/mean/expectation, may be calculated for the printed area distribution associated with the printed area. As discussed in more detail below, the CDF associated with deprotection of resist for the printed area may be used to determine an average printed area (APA) and/or an average printed volume (APV) relating to variation in printing due to the stochastic randomness that are not supposed to be printed in the defined area (volume) of interest. As another example, a second moment, indicative of the standard deviation/variance, may be calculated for the printed area distribution associated with the printed area. The printed area distribution may be a 3D printed area distribution associated with the 3D printed area such that the second moment may be indicative of the standard deviation/variance of a printed volume relating to variation in printing due to the stochastic randomness that are not supposed to be printed in the defined area (volume) of interest. As discussed in more detail below, the CDF associated with deprotection of resist for the printed area may be used to determine the standard deviation (e.g., the square root of the variance (sqrt(Var(A)), where A is the defined printed area)). In this way, different moments, such as the first statistical moment of the random variable (e.g., indicative of the average), the second statistical moment of the random variable (e.g., indicative of the variance), or other moments of the random variable, may be calculated.

For example, APA/APV may comprise a statistical expectation of the defined printed area (e.g., defined printed volume). APA/APV may be more lithographically meaningful than merely a probability of printing because APA/APV, in effect, assigns higher “weights” to larger printed areas. Further, APA/APV may be analytically calculated by integrating over a defined area (volume) (such as the (3D) sidelobe printability control domain (SPCD)) for a deprotection function (e.g., using a CDF, such as a Gaussian Random Field deprotection function), as discussed in more detail below. In this way, APA/APV may use the CDF, sampling random deprotection at various points within the defined area, so that the CDF is of a univariate random vector.

As another example, the standard deviation may comprise a probative stochastic metric to characterize the stochastic-caused variation of lithographically patterned elements, such as vias/contact holes. Similar to the APA/APV metric, the standard deviation of the printed area may be analytically calculated (e.g., using a CDF, such as Gaussian Random Field deprotection function). As discussed further below, the standard deviation may use the CDF of the bivariate random vector, with a first component deprotection at point xi and a second component deprotection at point x₂.

The one or more moments may be probative stochastic metrics for different aspects of the layout design. In particular, in one or some embodiments, the one or more moments may be probative as to the printability of one or more elements in the layout design (such as one or more elements in the layout design that are not designated for printing). As one example, SRAFs are for assisting in the printing of other elements (e.g., main features) but are not to be printed themselves. As such, printing of SRAFs is rare, random, and may be caused by stochastic phenomena. As another example, pinching or bridging between two or more lithographic features (e.g., between the tips of two trenches) may likewise be caused by stochastic phenomena. The first moment of the printed area distribution, such as APA/APV, which is indicative of the average printed area, may be probative of the likelihood of printing for element(s) not designated for printing.

As another example, the metric of top surface roughness (TSR) may be calculated by estimating the variance and standard deviation of the top resist surface vertical position over a certain area of interest. By analogy with the commonly used line edge roughness (LER) or line width roughness (LWR) metrics, TSR may be assigned the value of 3 times the standard deviation of the top resist surface position over this area of interest.

As still another example, the power spectral density (PSD) of the top surface roughness may be calculated as a more detailed characterization of the top surface roughness, quantifying the top surface variability over its various spatial frequencies. Similar to PSD calculation for the straight edge formed in the resist, PSD of the top surface may be calculated by simulating the random variation of the top surface along a certain straight line in the area of interest, calculating the Fourier transformation of this random variation, and considering the square of the absolute value of this Fourier transformation for a certain spatial frequency harmonics as a PSD value corresponding to this spatial frequency.

Alternatively, or in addition, the one or more moments may be probative as to one aspect of printability (e.g., variability associated with printing) of one or more elements in the layout design that are designated for printing. As one example, vias/contact holes (CH) may be considered main features for printing. Stochastic phenomena may affect the printing of those main features, such as the variability of those printed main features. As such, one or more printed area metrics, such as standard deviation (or other metric derived from variance) of the printed area, may be probative of the variability of printing of main features designated for printing. In this way, the second moment of the printed area distribution may be a better metric for assessing the printing of the main features.

Alternatively, multiple moments, such as the first moment and the second moment, may be used in combination. In one or some embodiments, responsive to identifying a non-linear function associated with a physical meaningful quantity, multiple moments may be used. For example, calculating a metric indicative of the expectation of resistance (such as in the context of a via, which is discussed further below and may be based on a non-linear function), the formulation may use a Taylor expansion as a linear combination of a first moment of the expectation of the printed area and a second moment of the variance of the printed area.

Thus, the analytical printed area metric may be indicative of the likelihood of whether, within a respective printed area, any one, any combination, or all of the following may occur: SRAF printing; pinching or bridging; the lithographic process results in the complete removal of the resist material; the lithographic process results in the complete retention of the resist material; variance of main feature printing; or the like.

The analytical printed area metric may thus be indicative of the success or failure of critical sections of the layout design identified as particularly susceptible to failure. In this way, the analytical printed area metric may: (i) provide a computationally efficient way to calculate the printed area metric indicative of the outcome of the lithographic process with respect to the stochastic randomness in exposure and the resist process; and/or (ii) enable the improvement (or optimization) of the illumination (e.g., source) and/or the mask (e.g., with regard to source-mask optimization (SMO) or optical proximity correction (OPC) algorithms) in order to reduce or mitigate the effects of stochastic randomness on the yield of the lithographic process. Examples of lithographic processes are disclosed in US Patent Application Publication No. 2015/0067628 A1 and US Patent Application Publication No. 2019/0102501 A1, both of which are incorporated by reference in their entirety.

Specifically, the analytical printed area metric may efficiently identify certain critical sections prone to failure (based on the determined printed area metrics, such as printability and/or variability of printing) in order to modify one or both of the intensity (or other light exposure parameter) or the resist (such as the pattern in the layout design) to reduce the possibility of failure. In this way, the methodology makes it practical to calculate the printed area metric without multiple iterations of the SMO, OPC or verification algorithms for the entire die of the integrated circuit. This is unlike typical analysis methodologies, such as based on Monte Carlo simulations, that make the use of experimental exposures and measurements in multiple iterations of the mask preparation flow impractical. Rather, the analytical printed area metric for one or more defined printed areas may be calculated within a reasonable time, with results comparable to Monte Carlo simulations, allowing quick verification of the OPC/SMO solutions and to calculate the OPC/SMO solutions, thereby reducing the probability of stochastic failure and improving the yield, particularly in the EUV lithography.

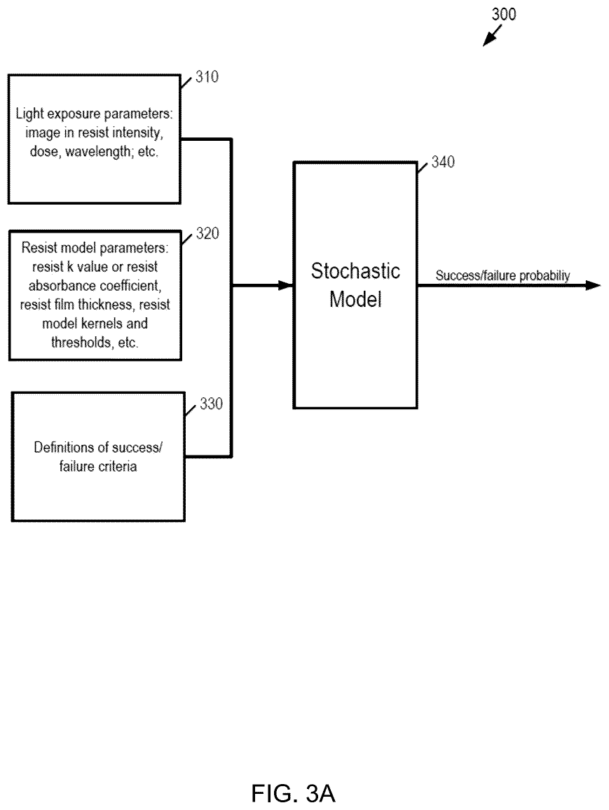

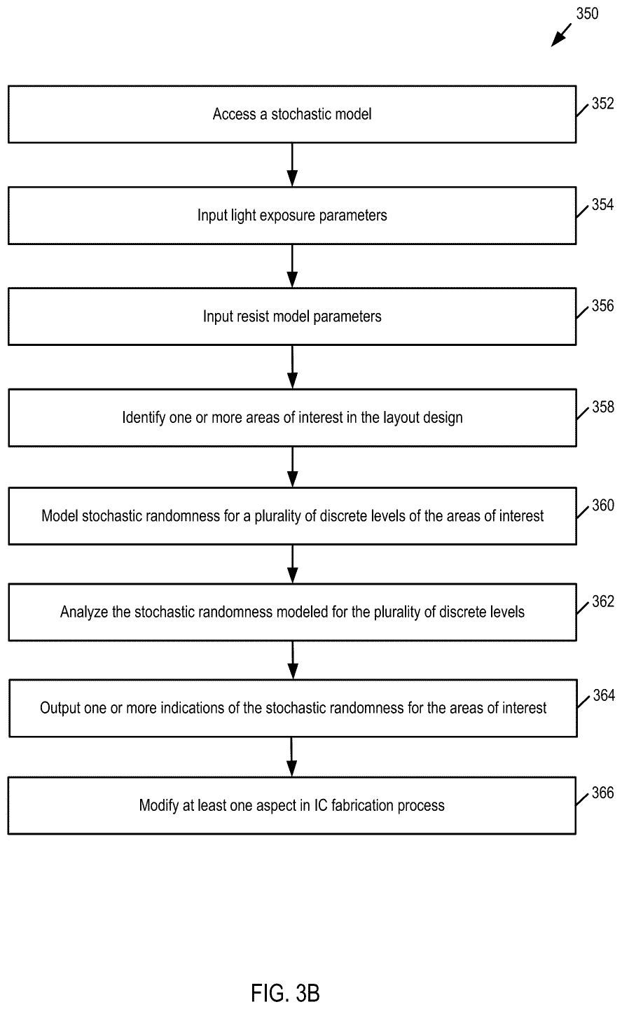

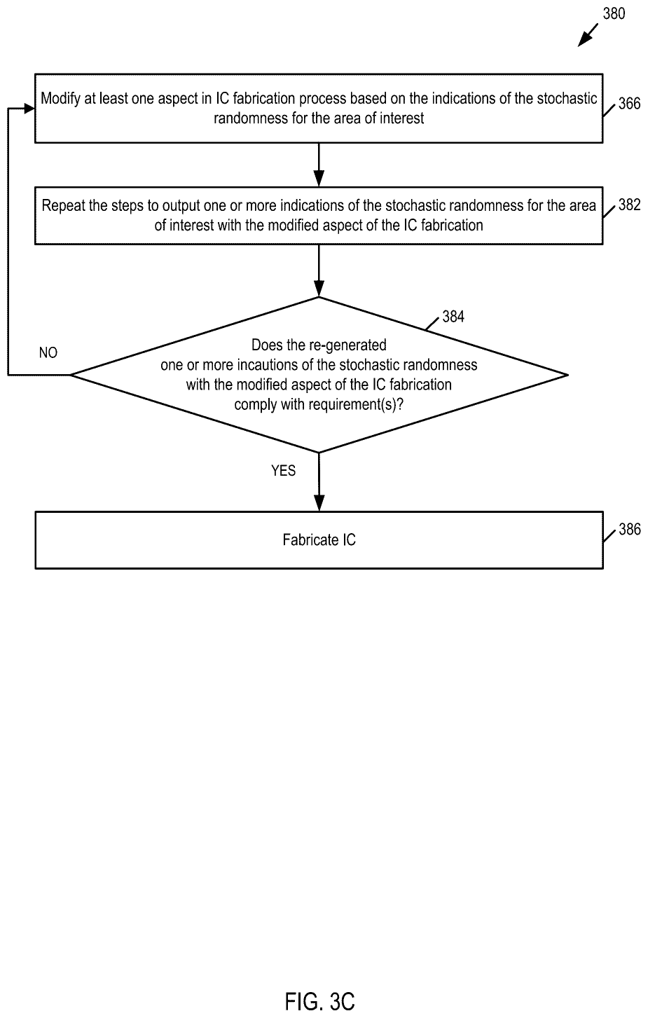

Referring back to the figures, FIG. 3 illustrates a block diagram 300 of inputs to and output(s) from the stochastic model 340. As discussed above, the stochastic model may receive one or more inputs, including any one, any combination or all of: one or more light exposure parameters 310 (e.g., any one, any combination, or all of: image in resist intensity; dose; wavelength); one or more resist model parameters 320 (e.g., any one, any combination, or all of: resist k (extinction coefficient) value or resist absorbance coefficient; resist film thickness; resist model kernels and thresholds); and definition(s) of success and/or failure criteria 330 (e.g., using a cutline; defining isolation set(s) in which success is defined as the complete retention of the resist material therein; defining integrity set(s) in which success is defined as the complete removal of the resist material therein; etc.). Further, the output of the stochastic model 340 may comprise success and/or failure probability (e.g., a probability distribution function).

FIG. 3B is a flow diagram 350 of generating and using the success/failure probability using the stochastic model. At 352, the stochastic model is accessed. At 354, light exposure parameters, such as discussed above, may be input to the stochastic model. At 356, resist model parameters are input to the stochastic model as well. At 358, one or more areas of interest (one or more volumes of interest) may be identified in the layout design. For example, the one or more areas of interest may be user-defined areas (volumes) of interest identified based on a user input.

At 360, the stochastic randomness of interest, using the stochastic model and the various inputs, may be modeled for each of a plurality of discrete levels included in the identified critical area(s). For example, a probability density function may be generated (e.g., modeled) that defines deprotection at a collection of discrete points, such as in one, some, or each of the plurality of levels of the one or more areas of interest in the layout design. At 362, the stochastic randomness of interest modeled for each of the plurality of levels within the one or more areas of interest may be analyzed across the plurality of levels. For example, the stochastic randomness of interest modeled for each of the plurality of levels may be interpolated to generate a 3-dimentional distribution function of the stochastic randomness of interest for the areas of interest. At 364, one or more indications of the stochastic randomness (e.g., the success or the failure probability of the lithographic process) based on the 3-dimentional distribution function of the stochastic randomness of interest may be generated and output.

In some embodiments, one or more aspects of the IC fabrication process may be modified based on one or more indications of the stochastic randomness (e.g., the success or the failure probability of the lithographic process). For example, responsive to the failure probability being greater than a predetermined amount, the one or more aspects of the IC fabrication process may be modified. For example, at 366, at least one aspect in the IC fabrication process may be modified based on the one or more indications of the stochastic randomness of the areas of interest. Modifying at least one aspect of the IC fabrication may include, but not be limited to, modifying at least one aspect of in the lithographic process and/or modifying at least one aspect of a circuit/resist design. For example, the indication of the stochastic randomness of interest (e.g., success/failure probability) may be used in a cost function for one or both of source optimization or mask optimization. In optimizing the lithographic process, a cost function may be used. The cost function may take one of several forms suitable for the goal of optimization and represent one or more figures of merit (e.g., a metric of the system). An example of cost function analysis is disclosed in US Patent Application Publication No. 2015/0067628, incorporated by reference herein in its entirety. The optimization process may find one or more parameters of the system that optimizes (e.g., minimizes or maximizes) the cost function, under a certain constraint if any. When the cost function is optimized (e.g., minimized or maximized), the one or more figures of merit represented by the cost function are optimized (e.g., minimized or maximized). In a lithography apparatus, an example of a cost function comprises:

$$Cost = F * D \qquad ( 2 )$$

where F equals the frequency of the pattern and D equals the printing difficult factor. In some implementations, the generated probability may be factored into the cost function, such as incorporated into D.

FIG. 3C is a flow diagram 380 illustrating another example of using the stochastic model. Again, at 366, at least one aspect in the IC fabrication process may be modified based on the one or more indications of the stochastic randomness of the areas of interest. At 382, 352-364 of FIG. 3B may be repeated to output one or more indications of the stochastic randomness for the area of interest that are generated with the modified aspect(s) in the IC fabrication process. At 384, whether the one or more indications of the stochastic randomness for the area of interest generated with the modified aspect(s) of the IC fabrication comply with requirement(s)/rule(s) may be determined. If the one or more indications of the stochastic randomness for the area of interest generated with the modified aspect(s) of the IC fabrication do not comply with the requirement(s)/rule(s), the flow may continue to 366 of FIG. 3B. Then, 366, 382, 384 of FIG. 3C may be repeated until the generated one or more indications of the stochastic randomness with the modified aspect of the IC fabrication process comply with the requirement. If the one or more indications of the stochastic randomness for the area of interest comply with the requirements, the flow may continue to 386. At 386, the IC fabrication is performed with the one or more aspects that generate the one or more indications of the stochastic randomness complying with the requirements/rules.

As discussed above, various stochastic models are contemplated. For example, a continuous random field model, a Gaussian random field model, or an MVN distribution model may be used. Further, success or failure of a lithographic event may be defined as deprotection along a line or a volume. In this way, using one of the stochastic models and the defined success or failure may be used to calculate the probability of the line or volume deprotection, which may be useful for failure rate estimation.

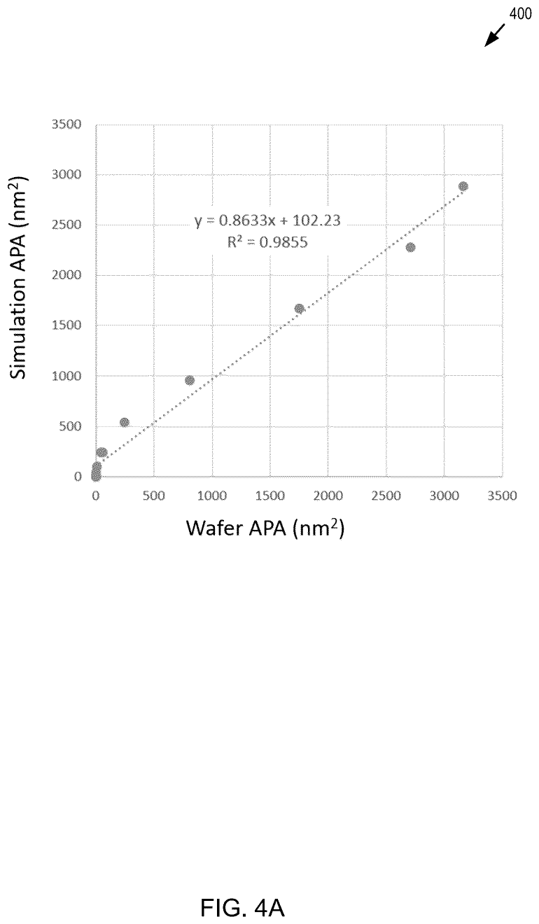

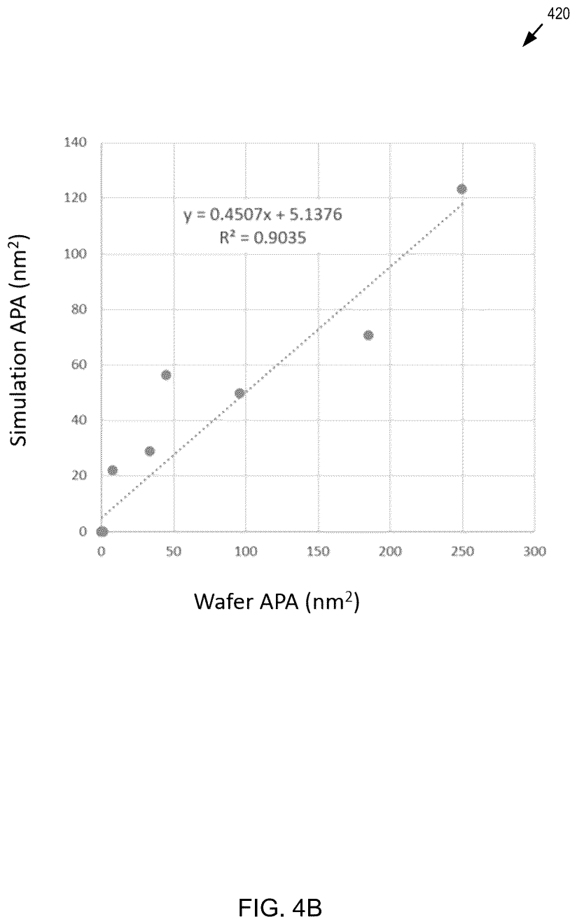

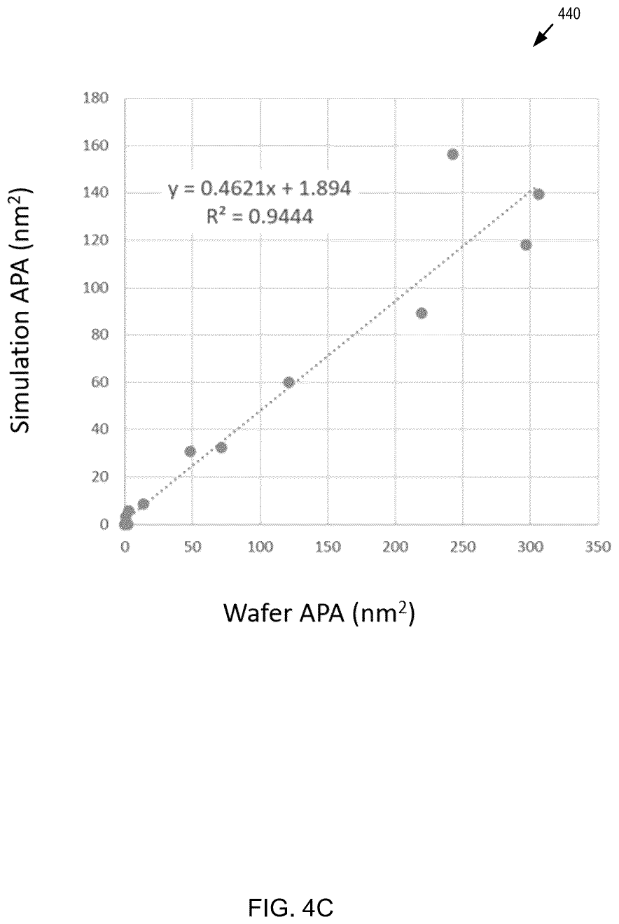

FIGS. 4A-4C are graphs 400, 420, 440 illustrate SRAF relative APA calculated using the stochastic model vs. SRAF relative APA on wafer identified using SEM images. Three gauges were picked for the model threshold optimization and respective FIGS. 4A, 4B, and 4C represent the result with each of the three gauges.

The distribution charts on FIGS. 4A-4C illustrate a noticeable correlation between the Average Printing Area (APA) simplistically analyzed using the stochastic model and the wafer average SRAFs printing area measured using a SEM. As discussed above, the stochastic model may be based on Gaussian Random Field deprotection.

Hereinafter, various examples of modeling and calculation of the various types of stochastic randomness in a respective level of the plurality of levels for the area of interest.

For background, for a given continuous image intensity in resist, I(x), and a given resist model kernel, G(x), a deprotection (e.g., a concentration of deprotected functional groups in the resist) may be modelled as:

$${n}_{d} ( x ) = G ( x ) ⊗ I ( x ) ) \qquad ( 3 )$$

A simplistic resist development model, which does not account for stochastic phenomenon, is illustrated in the illustration 500 in FIG. 5A with retained resist 510 and removed resist 520. In particular, the simplistic resist development model, for a given development threshold T, may be represented as follows:
at points x where n_{d}(x)>T, the resist is removed (e.g., dissolved);
at points x where n_{d}(x)<T, the resist is retained;
the points x where n_{d}(x)=T form the edge.

For purposes of illustration, the deprotected areas are etched into the isolating substrate and filled with the metal to form interconnects.

In accounting for simplistic stochastic exposure and the resist model, the result of the imaging model is I(x), a continuous image intensity in resist, defined at every point of the resist film. Using the given I(x), one may calculate the random absorbed photon density, resulting from the exposure by N_{hν} photons as:

$${n}_{h v} ( x ) = {\sum }_{i = 1}^{{N}_{h v}} δ ( x - {x}_{i} ) \qquad ( 4 )$$

where the sites of absorbed photons, xᵢ, are selected to satisfy the photon absorption statistics (e.g., as ˜Poisson(<n>) for each voxel in the resist, with <n> denoting the average number of photons absorbed in this voxel). The stochastic deprotection resulting from these absorbed photons is:

$${n}_{d} ( x ) = {\sum }_{i = 1}^{{N}_{h v}} G ( x - {x}_{i} ) \qquad ( 5 )$$

The simplistic resist development model, which does account for at least some stochastic phenomenon, is illustrated in the illustration 550 in FIG. 5B. The simplistic resist development model assumes that each photon contributes equally to the process of making the resist dissolvable. Alternatively, the resist development model may consider other stochastic phenomena, such as chemical stochastic phenomena, and/or may consider other complicating factors, such as resist saturation effects, development/3D effects, or reaction-diffusion non-linearity. For example, with regard to resist saturation, the initial photons that fall onto the resist film may trigger the reaction without saturation effects; however, the later photons, which fall on the molecules that have already at least partly reacted to the light, may be subject to saturation resulting in the later photons potentially have less chemical effect.

As discussed in more detail below, using the above simplistic resist model and Central Limit Theorem (CLT), at any point in resist, the deprotection is distributed normally. The parameters of the normal distribution are discussed further below at Equations 41 and 42. Knowing this normal distribution, one may calculate various probabilities related to a resist deprotection. For example, one, some or all of the following probabilities may be calculated:
(i) Pr(n_{d}(x₀)>T): probability that a given point in the resist, x₀, is removed/dissolved.
(ii) all points in the resist, where the probability to be removed is greater than 99.7% (3-sigma), for each point.
(iii) all points in the resist, where the probability to be retained is 99.7% or greater (3-sigma), for each point.

The probabilities calculated are merely for illustration purposes; other probability calculations are contemplated. Further, estimating a probability of a simultaneous removal of a given set of points in the resist is based on the knowledge of the joint probability density for deprotection sampled in all of these points (e.g., covariances between spatially separated points, in addition to means and variances).

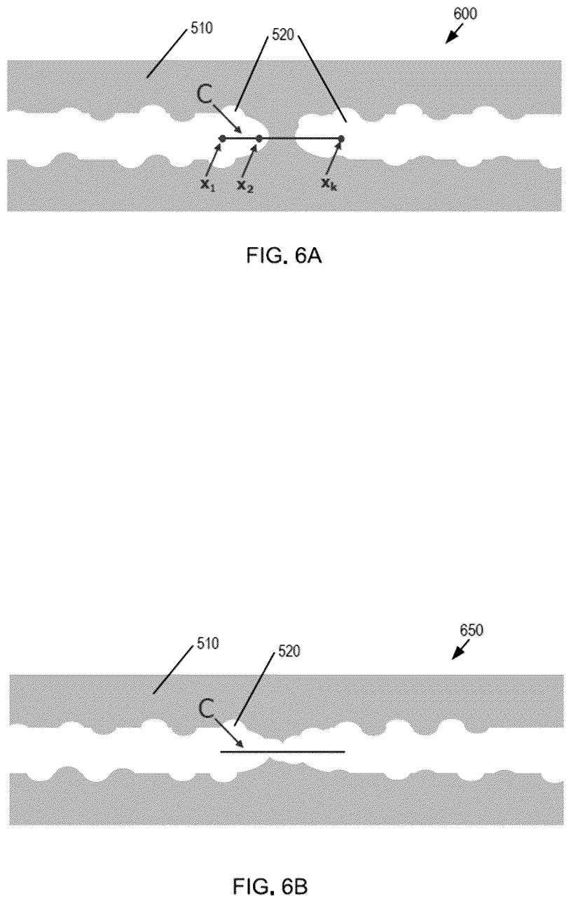

FIGS. 6A-B illustrate a first resist representation accounting for stochastic effects using a cutline C to determine whether pinching has not occurred (as shown in illustration 600 of FIG. 6A) or whether pinching has occurred (as shown in illustration 650 of FIG. 6B). The cutline, C, may be placed across a location, such as where the pinching probability is to be estimated. As discussed above, various parts of the layout may comprise critical sections or points. As shown in FIGS. 6A-B, the probability may be calculated at all points on a cutline C being fully deprotected, as represented by:

$$Pr ( {n}_{d} ( x ) > T , for all x ∈ C ) \qquad ( 6 )$$

This probability may be a reasonably good estimate as to whether pinching is occurring in the vicinity of the cutline. Further, calculating the probability may be based on knowledge of the joint probability density function for deprotection along the cutline.

Further, means and covariance of the deprotection function may be calculated for a set of points according to one or more of the following steps:

Step 1: Mean, Variance and Spatial Covariance of Deprotection Resulting from a Single Absorbed Photon

Initially, means, variances and covariances of deprotection resulting from a single photon at a pair of observation points may be calculated. Specifically, the coordinates, X, of an absorption point for a single photon absorbed in a resist, within a simulation area V, form a 3-dimensional random vector with a probability density function given by:

$${f}_{X} ( x ) = β \cdot α ( x ) I ( x ) , \qquad ( 7 )$$

where β=(∫_{V}α(x)I(x)dx)⁻¹ is a normalization constant, α(x) is absorption coefficient and I(x) is the image intensity in resist. The values of deprotection from a single (e.g., the first) photon,

$${n}_{1}^{( l )} and {n}_{1}^{( m )} ,$$

at any two observation points xₗ and xₘ are the deterministic (non-random) functions of this random photon absorption point X:

$${n}_{1}^{( l )} = G ( {x}_{l} - X ) {n}_{1}^{( m )} = G ( {x}_{m} - X ) \qquad ( 8 )$$

Denoting by γ either of the indices l or m, the means, variances and covariances of these two deprotection values may be written as follows:

$$E ( {n}_{1}^{( γ )} ) = β {\int }_{V} G ( {x}_{γ} - x ) α ( x ) I ( x ) dx , \qquad ( 9 )$$

$$\begin{matrix}Var ( {n}_{1}^{( γ )} ) = E ( {( {n}_{1}^{( γ )} )}^{2} ) - {( E ( {n}_{1}^{( γ )} ) )}^{2} \\ = β {\int }_{V} {G}^{2} ( {x}_{γ} - x ) α ( x ) I ( x ) dx - ( {β ( {\int }_{V} G ( {x}_{γ} - x ) α ( x ) I ( x ) dx )}^{2}\end{matrix} \qquad ( 10 )$$

$$Cov ( {n}_{1}^{( l )} , {n}_{1}^{( m )} ) = E ( {n}_{1}^{( l )} {n}_{1}^{( m )} ) - E ( {n}_{1}^{( l )} ) E ( {n}_{1}^{( m )} ) = β {\int }_{V} G ( {x}_{l} - x ) G ( {x}_{m} - x ) α ( x ) I ( x ) dx - ( β {\int }_{V} G ( {x}_{l} - x ) α ( x ) I ( x ) dx ) ( β {\int }_{V} G ( {x}_{m} - x ) α ( x ) I ( x ) dx ) , \qquad ( 11 )$$

where E( ), Var( ) and Cov( ) denote, respectively, the expectation (i.e. mean or average), variance and covariance of their arguments.

One may now consider k observation points in the simulation area V of the resist, {x₁, x₂, . . . , xₖ}, and the values of deprotection

$${n}_{1} = \{ {n}_{1}^{( 1 )} , {n}_{1}^{( 2 )} , … , {n}_{1}^{( k )} \}$$

resulting in each of these points from a single (e.g. the first) photon absorbed in this simulation area. The equations 9, 10 and 11 provide the values of mean and variance of deprotection sampled at any of these observation points and the value of covariance for a pair of deprotection values sampled at any pair of these observation points.
Step 2: Mean, Variance and Spatial Covariance Resulting from a Given Fixed Number of Absorbed Photons, Application of CLT

Next, one may consider the deprotection values resulting from a given number, N_{hν}, of photons absorbed within the simulation area V. These values of deprotection are sampled at k observation points in the resist, {x₁, x₂, . . . , xₖ}. We denote

$${n}_{j} = \{ {n}_{j}^{( 1 )} , {n}_{j}^{( 2 )} , … , {n}_{j}^{( k )} \}$$

the values of deprotection resulting from the j-th absorbed photon (1≤j≤N_{hν}) in the resist, and the following notation may be used:

$$n = {\sum }_{j = 1}^{{N}_{h v}} {n}_{j} \qquad ( 12 )$$

for the deprotection resulting from all N_{hν} photons, sampled at the observation points. One may note that each photon is absorbed independently of other photons, and the coordinates X of the sites of absorption are independent identically distributed random variables with their common probability density given by equation 7. Correspondingly, the values of deprotection at the sampling points, resulting from each photon, given by equation 8, are independent identically distributed random variables as well. As a result, the mean, variance and spatial covariance values for deprotection resulting from all N_{hν} photons may be given by:

$$E ( {n}^{( γ )} ) = {N}_{h v} E ( {n}_{1}^{( γ )} ) = β {N}_{h v} {\int }_{V} G ( {x}_{γ} - x ) α ( x ) I ( x ) dx , \qquad ( 13 )$$

$$Var ( {n}^{( γ )} ) = {N}_{h v} Var ( {n}_{1}^{( γ )} ) = β {N}_{h v} {\int }_{V} {G}^{2} ( {x}_{γ} - x ) α ( x ) I ( x ) dx ) - {{N}_{h v} ( β {\int }_{V} G ( {x}_{γ} - x ) α ( x ) I ( x ) dx )}^{2} \qquad ( 14 )$$

$$\begin{matrix}Cov ( {n}^{( l )} , {n}^{( m )} ) = {N}_{h v} Cov ( {n}_{1}^{( l )} , {n}_{1}^{( m )} ) \\ = β {N}_{h v} {\int }_{V} G ( {x}_{l} - x ) G ( {x}_{m} - x ) α ( x ) I ( x ) dx ) - \\ {N}_{h v} ( β {\int }_{V} G ( {x}_{l} - x ) α ( x ) I ( x ) dx ) ( β {\int }_{V} G ( {x}_{m} - \\ x ) α ( x ) I ( x ) dx )\end{matrix} \qquad ( 15 )$$

Furthermore, because each term in the sum of equation 12 represents an independent identically distributed random vector with a finite values of mean (in equation 9), variance (in equation 10) and covariance (in equation 11) of its components, the Central Limit Theorem (CLT) may be applied to the sum in equation 12.

As discussed above, the multidimensional CLT may be applied. Examples of descriptions for multidimensional CLT include the following (both of which are incorporated by reference in their entirety): https://en.wikipedia.org/wiki/Central_limit_theorem#Multidimensional_CLT; Van der Vaart, A. W., Asymptotic statistics. New York: Cambridge University Press. ISBN 978-0-521-49603-2. LCCN 98015176 (1998) (see, e.g., Section 2.18). One skilled in the art may apply the teachings of the references for CLT. It follows from the CLT that, for a sufficiently large number of absorbed photons N_{hν}, the random vector n may be well approximated by a Multivariate Normal (MVN) distribution, [symbol] (μ, Σ), with the value of its mean vector, μ, given by equation 13 and the entries of its covariance matrix, Σ, given by equations 14 and 15.

Because the latter result is valid for any selection of any finite number of sampling points in resist, the continuous distribution of deprotection is a Gaussian Random Field.

Step 3: The Case when the Number of Absorbed Photons is a Poisson Distributed Random Variable (Fixed Average Exposure Dose)

Equations 13, 14 and 15 were obtained based on the assumption of absorption of a given fixed number of photons, N_{hν}, within the simulation area V. The actual exposure control mechanisms in optical or EUV lithography do not allow to ensure the absorption of the exact prescribed number of photons. These exposure control mechanisms usually allow the control of the intensity of light falling on the photomask and the duration of exposure (or the value of the scanning velocity). As a result, only the average number of absorbed photons (or the average dose) may be controlled by such exposure mechanisms. The actual number of absorbed photons within the simulation area V in such realistic exposure scenarios is a Poisson-distributed random variable, with the value of the rate parameter of this Poisson distribution equal to the average number of photons absorbed within the simulation area, N̅_̅{̅h̅ν̅}̅:

$${N}_{h v} ∼ Poisson ( \overline{{N}_{h v}} ) . \qquad ( 22 )$$

The sum in the equation for a total deprotection (equation 12) therefore becomes a sum with a random (Poisson-distributed) number of independent identically distributed terms. As known to those skilled in the art of statistics and probability theory, the distribution of such sum is a compound Poisson distribution. The expressions for the mean, variance and covariance for the total deprotection (equation 12) may be obtained using the properties of the Poisson distribution and the formulae known as the law of total expectation, the law of total variance and the law of total covariance, known to those skilled in the art of statistics and probability theory. Application of these formulae gives, for the case of fixed average exposure dose:

$$E ( {n}^{( γ )} ) = \overline{{N}_{h v}} E ( {n}_{1}^{( γ )} ) = β \overline{{N}_{h v}} {\int }_{V} G ( {x}_{γ} - x ) α ( x ) I ( x ) dx , \qquad ( 23 )$$

$$Var ( {n}^{( γ )} ) = \overline{{N}_{h v}} E ( {( {n}_{1}^{( γ )} )}^{2} ) = β \overline{{N}_{h v}} {\int }_{V} {G}^{2} ( {x}_{γ} - x ) α ( x ) I ( x ) dx , \qquad ( 24 )$$

$$Cov ( {n}^{( l )} , {n}^{( m )} ) = \overline{{N}_{h v}} E ( {n}_{1}^{( l )} {n}_{1}^{( m )} ) = β \overline{{N}_{h v}} {\int }_{V} G ( {x}_{l} - x ) G ( {x}_{m} - x ) α ( x ) I ( x ) dx . \qquad ( 25 )$$

After calculating the means and covariances of the normally distributed deprotection at the observation points, n, the joint probability density for the corresponding Multivariate Normal (MVN) distribution, [symbol] (μ, Σ), may be written as:

$$f ( n ) \frac{- 1}{\sqrt{{( 2 π )}^{k} det ( \sum )}} exp ( - \frac{1}{2} {( n - μ )}^{T} {\sum }^{- 1} ( n - μ ) ) \qquad ( 26 )$$

where the components of the parameters of this MVN distribution (the mean vector μ and the covariance matrix Σ) follow from equations 23 and 25:

$${μ}_{γ} = β \overline{{N}_{h v}} {\int }_{V} G ( {x}_{γ} - x ) α ( x ) I ( x ) dx \qquad ( 27 )$$

$${\sum }_{l m} = β \overline{{N}_{h v}} {\int }_{V} G ( {x}_{l} - x ) G ( {x}_{m} - x ) α ( x ) I ( x ) dx . \qquad ( 28 )$$

With the known probability density function (PDF), one may calculate deprotection probability for a selected set of observation points as:

$$P r ( n > T ) = {\int }_{n > T} f ( n ) dn \qquad ( 29 )$$

which essentially reduces to a calculation of a cumulative density function (CDF) for a multivariate normal distribution at a point n=T (all components of n are equal T). As discussed above, there are various ways to approximate the CDF of an MVN distribution. For example, the Mahalanobis distance between n and T may be used as an indicator to quickly estimate the probability of deprotection.

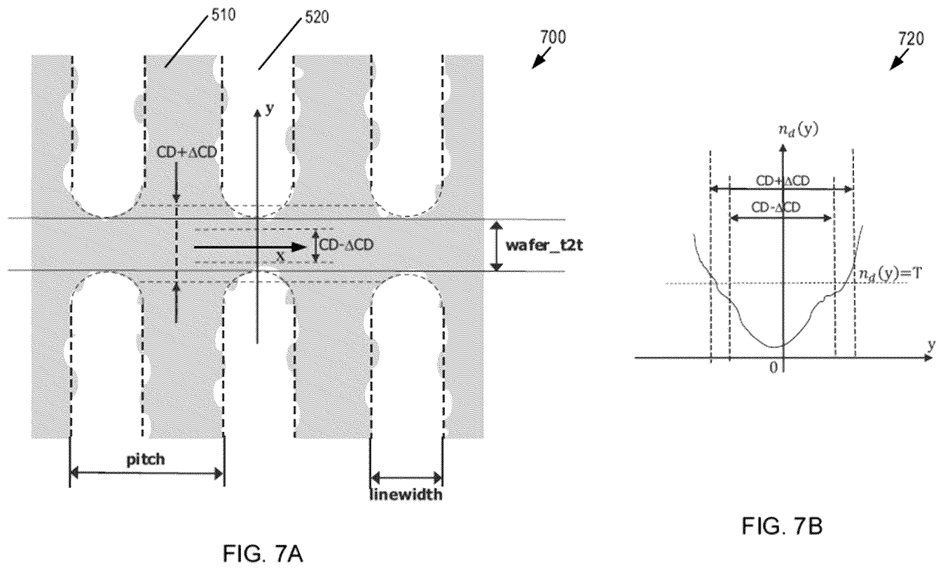

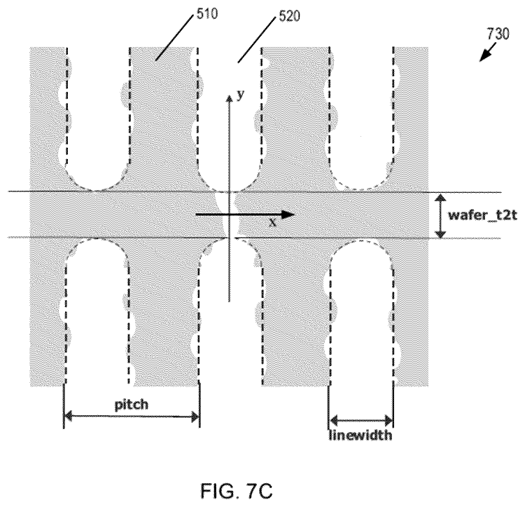

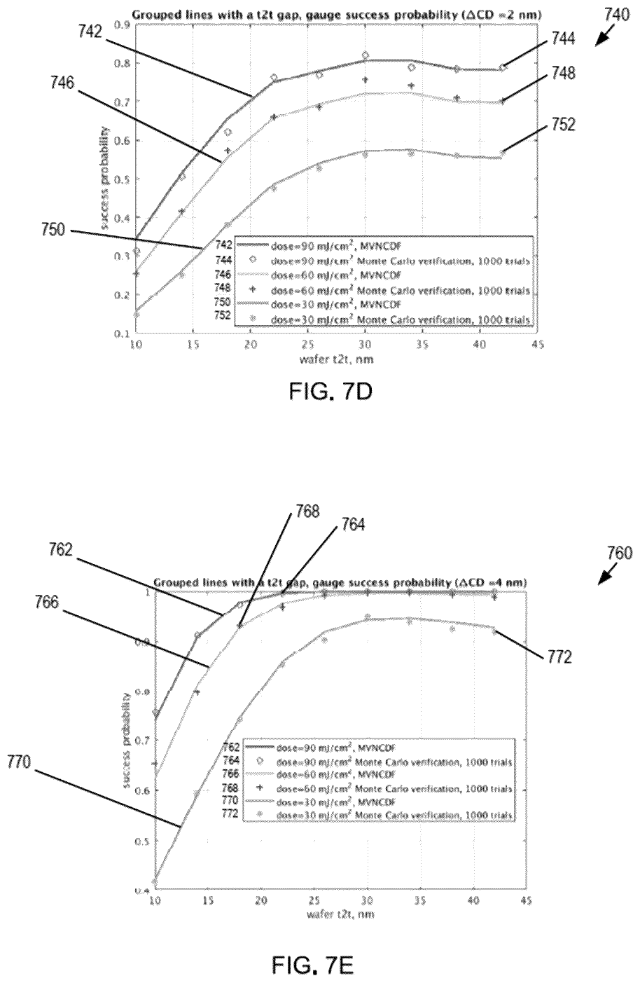

FIG. 7A is an illustration 700 of a second resist representation of grouped lines with a tip-to-tip (t2t) gap and the t2t gauge critical dimension (CD). FIG. 7B illustrates a graph 720 correlated to the second resist representation of FIG. 7A of the CD-based success criterion. FIG. 7C is another illustration 730 the second resist representation with pinching in the t2t gap. The following criteria are used for FIGS. 7A-C: pitch=44 nm; mask_linewidth=22 nm (on the mask, in wafer scale); wafer_t2t=10:4:42 nm; ΔCD=2 nm or 4 nm. Further, as discussed above, various definitions of success or failure are contemplated. For a given gauge, a successful exposure may be defined as the exposure resulting in a resist material removal (n_{d}(x)>T) in the interior of the line (|x|<0.5(CD−ΔCD)) and the resist material retention (n_{d}(x)<T) outside the line (|x|>0.5(CD+ΔCD)). One choice for ΔCD is 10% of the CD. Under this definition, the probabilities of success and failure are:

$${P}_{s u c c e s s} = Pr ( ( {n}_{d} ( y ) < T , for \vert y \vert < 0. 5 ( C D - Δ C D ) ) and ( {n}_{d} ( y ) > T , for \vert y \vert > 0.5 ( CD + Δ C D ) ) ) \qquad ( 30 )$$

$${P}_{failure} = 1 - {P}_{s u c c e s s} \qquad ( 31 )$$

As discussed above, using the disclosed methodology to calculate the probability, such as using MVNCDF, may provide comparable results to the computationally expensive Monte Carlo simulations. FIG. 7D illustrates a graph 740 of a comparison of MVNCDF versus Monte Carlo simulations for the second resist representation illustrated in FIGS. 7A-C for ΔCD=2 nm. FIG. 7E illustrates a graph 760 of a comparison of MVNCDF versus Monte Carlo simulations for the second resist representation illustrated in FIGS. 7A-C for ΔCD=4 nm.

As shown in FIG. 7D for ΔCD=2 nm, the results are comparable for different doses: 30 mJ/cm²: 750 for MVNCDF versus 752 for Monte Carlo simulation; 60 mJ/cm²: 746 for MVNCDF versus 748 for Monte Carlo simulation; and 90 mJ/cm²: 742 for MVNCDF versus 744 for Monte Carlo simulation. Likewise, as shown in FIG. 7E for ΔCD=4 nm, the results are comparable for different doses: 30 mJ/cm²: 770 for MVNCDF versus 772 for Monte Carlo simulation; 60 mJ/cm²: 766 for MVNCDF versus 768 for Monte Carlo simulation; and 90 mJ/cm²: 762 for MVNCDF versus 764 for Monte Carlo simulation.

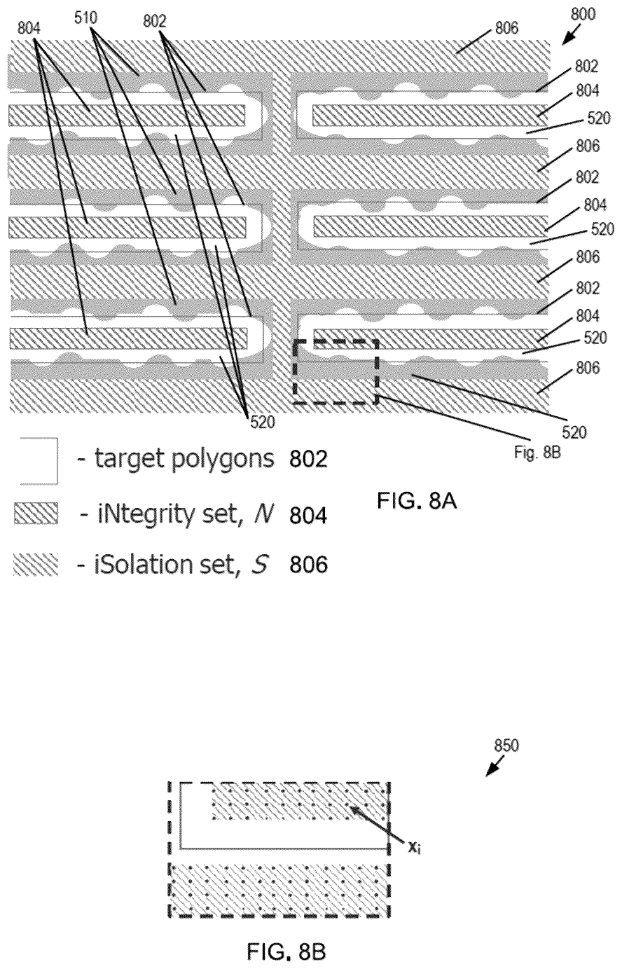

Further, success/failure may be defined in one of several ways, including based on integrity and/or isolation sets, as discussed above. FIG. 8A illustrates a third resist representation 800 of success probability estimation for target polygons 802 using integrity set N (804) and isolation set S (806). FIG. 8B is an expansion on a subsection 850 of the third resist representation of FIG. 8A, including xᵢ, a part of the integrity set N (804).

Specifically, for an interconnect, the integrity set N (804) may represent the core of the interconnect wire. To warrant that the wire is not cut anywhere, it is determined that the integrity set N (804) is fully deprotected. The isolation set S (806) may represent the core of the isolator. To warrant that the interconnect wires do not short anywhere, it is determined that the isolation set S (806) is fully protected. Thus, the integrity/isolation sets may be defined by applying, respectively, negative/positive bias to the target polygons (or various other shapes) and taking the interior/exterior of the resulting biased polygons (or various other shapes). Respectively, the probabilities of success or failure in exposing the pattern are:

$${P}_{s u c c e s s} = Pr ( ( {n}_{d} ( {x}_{i} ) > T , for all {x}_{i} ∈ N ) and ( {n}_{d} ( {x}_{i} ) < T , for all {x}_{i} ∈ S ) ) \qquad ( 32 )$$

$${P}_{failure} = 1 - {P}_{s u c c e s s} \qquad ( 33 )$$

Thus, calculating P_{success}, as defined above, for a generic pattern may involve filling the integrity set N (804) and the isolation set S (806) with the sampling points xᵢ (e.g., at least 100 sampling points; at least 1,000 sampling points) and calculating MVNCDF for the number of dimensions corresponding to the number of these sampling points. Alternatively, an indication of the probability may be based on estimating the MVNCDF value using the Mahalanobis distance and the χ² distribution (both discussed above).

### Example Stochastic Model

Consider a two-dimensional nominal optical aerial image [symbol] (\vec{r}) on a pixel located at \vec{r}=(x, y) just above the resist surface. One may assume that resist blurs the aerial image with a Gaussian diffusion of size Error!. The nominal intensity inside the resist Error! is given by the convolution of optical image with gaussian diffusion

$$G ( \vec{r} , {σ}_{d} ) = \frac{{e}^{- \frac{{r}^{2}}{2 {σ}_{d}^{2}}}}{2 {πσ}_{d}^{2}}$$

i.e.:

$$\hat{I} ( \vec{r} ) = {\hat{I}}_{a} ( \vec{r} ) ⊗ G ( \vec{r} , {σ}_{d} ) \qquad ( 34 )$$

The aerial intensity Iₐ(\vec{r}) may be used to calculate the nominal photon count \hat{N}(\vec{r}) on pixel by the relation:

$$\hat{I} ( \vec{r} ) = {\hat{I}}_{a} ( \vec{r} ) {N}_{0} / {I}_{0} \qquad ( 35 )$$

where I₀ and N₀ are the clear field optical intensity and clear field photon-count respectively. N₀ is obtained from the physical dose (D), pixel area (Δr²), and the energy of the photon (hν):

$${N}_{0} = \frac{Δ {r}^{2} D}{hv} .$$

Due to the stochastic effects, photon count (N(\vec{r})) at position(\vec{r}) may follow the Poisson distribution with mean \hat{N}(\vec{r}) (e.g., probability that photon count is

$$n = \frac{{\hat{N}}^{n} {e}^{- \hat{N}}}{n !} ) .$$

Hence, the count at a certain pixel may deviate from its nominal value by the noise ΔN(\vec{r})=N(\vec{r})−\hat{N}(\vec{r}). This noise in the incident photons translates to the noise in the optical image according to Equation 35 as:

$${I}_{a} ( \vec{r} ) = \hat{I} ( \vec{r} ) + Δ {I}_{a} ( \vec{r} ) \qquad ( 36 )$$

$$Δ {I}_{a} ( \vec{r} ) = ( {I}_{0} / {N}_{0} ) Δ N ( \vec{r} ) \qquad ( 37 )$$

The noise in the optical image may translate to the noise in the blurred resist image as:

$$I ( \vec{r} ) = {\hat{I}}_{r} ( \vec{r} ) + Δ {I}_{a} ( \vec{r} ) ⊗ G ( \vec{r} , {σ}_{d} ) \qquad ( 38 )$$

$$Δ {I}_{a} ( \vec{r} ) ⊗ G ( \vec{r} , {σ}_{d} ) = \frac{{I}_{0}}{{N}_{0} ( N ( \vec{r} ) ⊗ G ( \vec{r} ) - \hat{N} ( \vec{r} ) ⊗ G ( \vec{r} ) )} \qquad ( 39 )$$

In Equation 39, X=N(\vec{r})⊗G(\vec{r}, σ_{d}) is a stochastic variable obtained by convoluting a Poisson random variable with a Gaussian. The convolution with a Gaussian is equivalent to a weighted average with Gaussian weights. Therefore, by CLT, X is a normal random variable whose mean and variance is given by the relation:

$${μ}_{X} = \hat{N} ( \vec{r} ) ⊗ G ( \vec{r} , {σ}_{d} ) \qquad ( 40 )$$

$${s}_{X} = \hat{N} ( \vec{r} ) ⊗ {G}^{2} ( \vec{r} , {σ}_{d} ) \qquad ( 41 )$$

Hence, the average (μ_{I}) and standard deviation (s_{I}) of the stochastic resist intensity at a pixel at location r\vec{→}(I(r\vec{→}) in Equation 39 is given by:

$${μ}_{I} ( \vec{r} ) = {\hat{I}}_{r} ( \vec{r} ) \qquad ( 42 )$$

$${s}_{I} ( \vec{r} ) = ( {I}_{0} / {N}_{0} ) \sqrt{\hat{N} ( \vec{r} ) ⊗ {G}^{2} ( \vec{r} , {σ}_{d} )} \qquad ( 43 )$$

These parameters may provide the stochastic bounds to the resist intensity within a certain confidence interval. For a probability φ, the upper and lower bound to Iᵣ(\vec{→}r) are then calculated as:

$${I}_{r}^{Upper} ( \vec{r} ) = {\hat{I}}_{r} ( \vec{r} ) + α ( {I}_{0} / {N}_{0} ) \sqrt{\hat{N} ( \vec{r} ) ⊗ {G}^{2} ( \vec{r} , {σ}_{d} )} \qquad ( 44 )$$

$${I}_{r}^{Lower} ( \vec{r} ) = {\hat{I}}_{r} ( \vec{r} ) + α ( {I}_{0} / {N}_{0} ) \sqrt{\hat{N} ( \vec{r} ) ⊗ {G}^{2} ( \vec{r} , {σ}_{d} )} \qquad ( 45 )$$

where α is chosen such that for a standard normal variable x: Probability(−α≤x≤α)=φ (e.g., α=3 implies φ=0.997). The edge location is calculated where the resist intensity is equal to a certain threshold T (e.g., Iᵣ(\vec{→}r)=T).

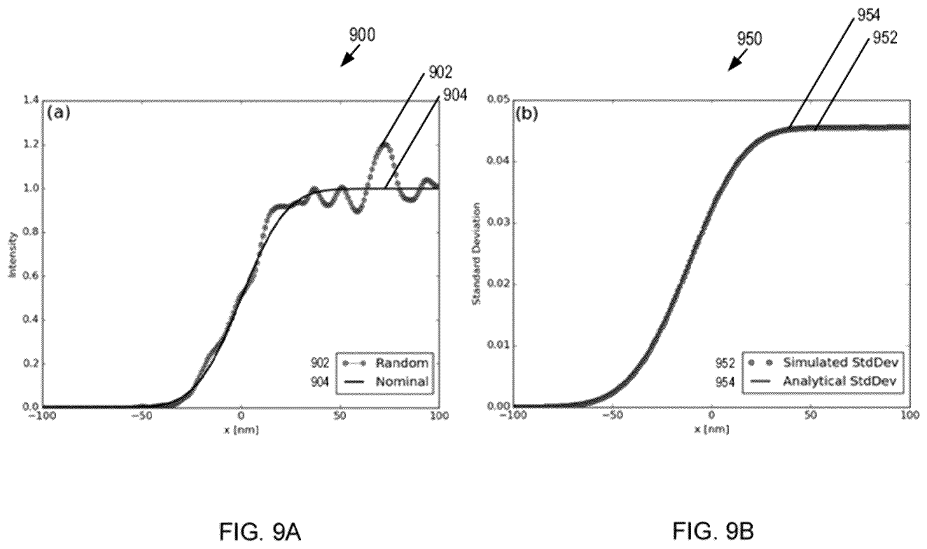

Consider a 1-D example with a simulated optical intensity cutline Error! for parameters η=25 nm, Error! nm, pixel size (Δx)=1 mm, Error! and Error!. FIG. 9A illustrates a graph 900 of the nominal resist intensity 904 (calculated from Equation 34) and one of the possible stochastic resist intensity profiles 902 due to photon shot noise (calculated from Equation 39). The standard deviation of intensity of each pixel is calculated using Equation 43 and compared to the one measured from 1000000 intensity profiles generated randomly according to Equation 39. As evident from the comparison shown in the graph 950 of FIG. 9B, the analytical standard deviation 954 matches perfectly with the measured standard deviation 952.

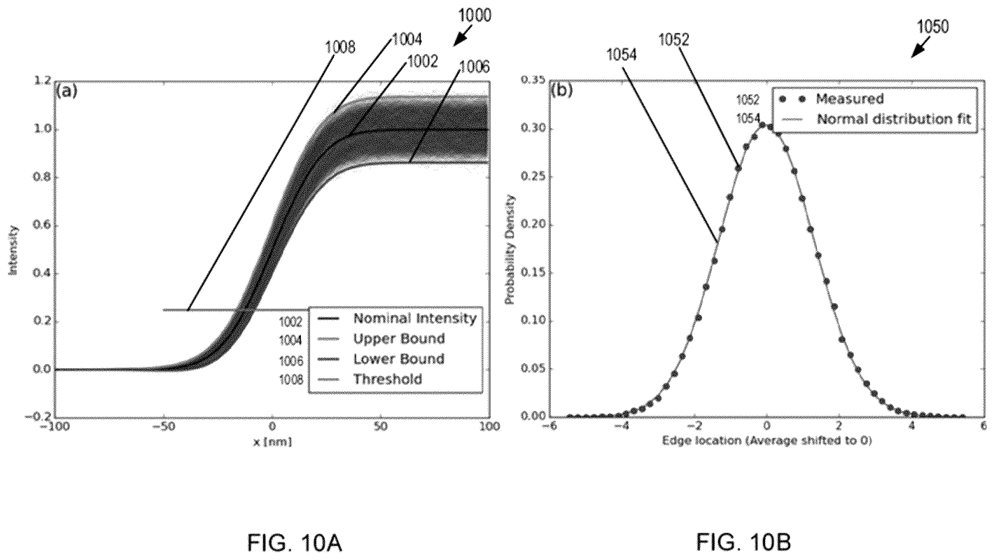

FIG. 10A shows a graph 1000 of how well the intensity bounds (upper bound 1004, lower bound 1006) calculated by Equations 44 and 45 (as compared to the nominal resist intensity 1002 or the threshold 1008) for α=3 are able to provide the bounds to the possible stochastic intensities with 99.7% confidence. The edge location is calculated for each of the random intensities for T=0.25, and its probability distribution is plotted in the graph 1050 of FIG. 10B. Measured 1052 are the probability distribution obtained from 1,000,000 runs while the line 1054 is a fit to normal distribution. In this way, it is shown that the probability distribution of the edge location resembles a normal distribution.

The bounds of variation in edge location for a given threshold may be approximated by the points where

$${I}_{r}^{Upper} ( \vec{r} ) = T , and {I}_{r}^{Lower} ( \vec{r} ) = T .$$

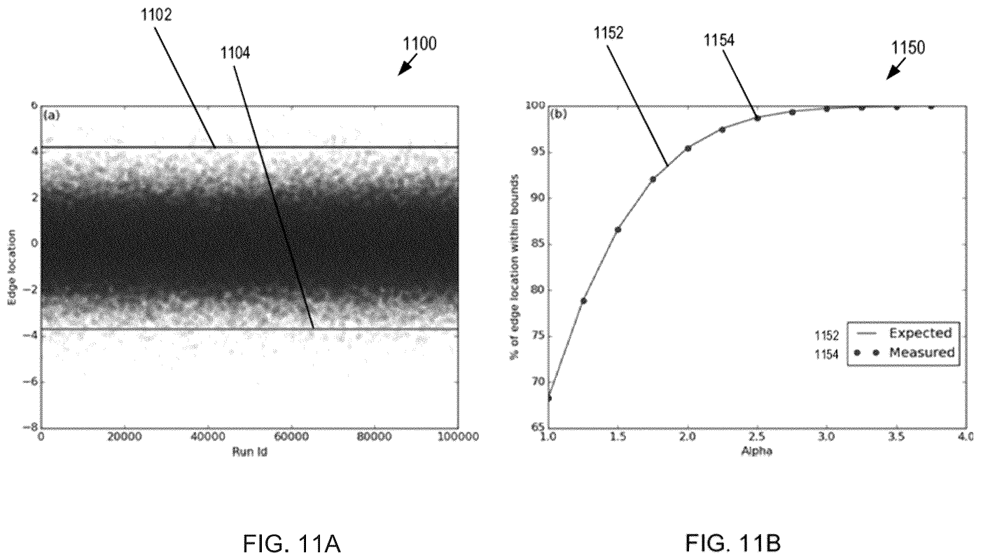

The accuracy of this approximation is shown in FIGS. 11A-B. Specifically, FIG. 11A illustrates a graph 1100 of the edge's location from 100000 random intensities, with upper line 1102 and lower line 1104 bounds for edge's location for α=3. FIG. 11B is a graph 1150 of the percent of the edge locations inside the analytical bounds vs α. Measured values 1154 are the measured probability from random runs while line 1152 is probability distribution as expected from CDF of normal distribution.

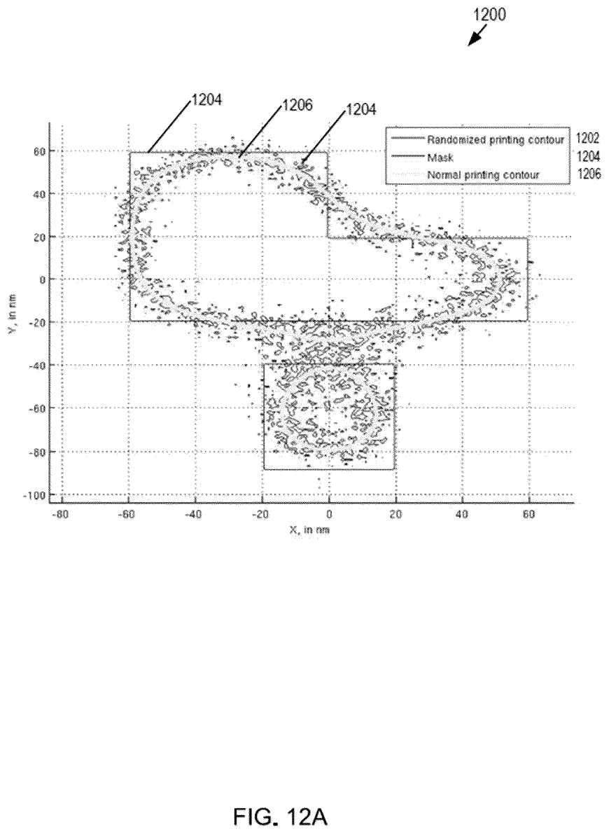

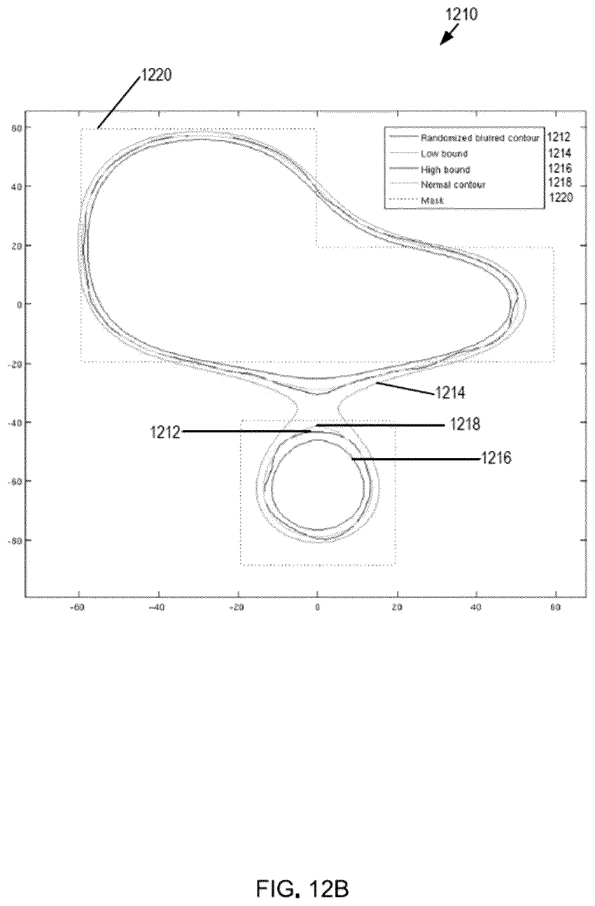

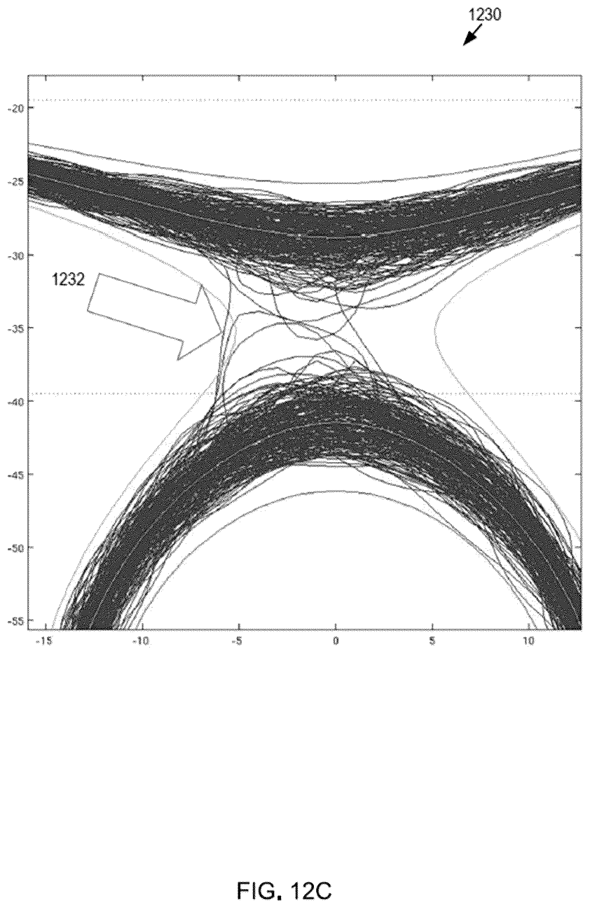

FIG. 12A is an illustration 1200 (with axes in nm) of the shot noise sample of 2D intensity illustrating the randomized printing contour (1202) d·Ir(x,y)=T and the normal printing contour (1206) d·I(x,y)=T for a printing mask (1204). FIG. 12B is an illustration 1210 of high bound 1216 and low bound 1214 contours, the normal contour 1218 and the sampled randomized blurred contour 1212 for mask 1220. FIG. 12C is an illustration 1230 of 200 randomized contours overlapping, where one highlighted random contour (identified by arrow 1232) did bridge.

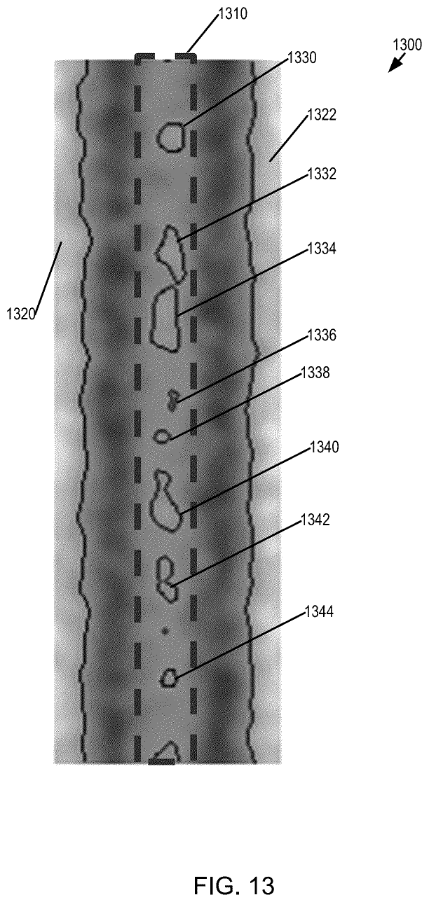

FIG. 13 is an illustration 1300 of a sidelobe printing control domain (SPCD). As discussed above, the printed area may be defined in order to generate the printed area metric associated thereto. With regards to FIG. 13, the printed area is defined as the area associated with SRAFs, as shown by box 1310 in between lines 1320, 1322 in which elements, such as 1330, 1332, 1334, 1336, 1338, 1340, 1342, 1344 associated with SRAFs, are printed due to stochastic phenomena.

As discussed above, APA comprises the statistical expectation (e.g., average) of the area of the printed features (e.g. the area of the printed SRAFs shown by 1330, 1332, 1334, 1336, 1338, 1340, 1342, 1344) within a user-defined area, such as the SPCD illustrated in FIG. 13. APA may thus be thought of as a printed area averaged over infinitely many trials. Further, APA may be estimated by running a sufficiently large number of Monte Carlo trials and averaging the printed areas, as discussed above. In contrast, the analytically-determined APA metric may be calculated efficiently without running multiple simulations.

In one or some embodiments, the APA for the printed area distribution may be calculated based on the CDF of the deprotection function. As one example, the mathematical derivation may be as follows:

$$APA = E ( {\int }_{SPCD} H ( n ( x ) - t ) dx ) \qquad ( 46 )$$

$$APA = ( {\int }_{SPCD} E ( H ( n ( x ) - t ) ) dx ) \qquad ( 47 )$$

$$APA = ( {\int }_{SPCD} ( 1 - {F}_{n ( x )} ( t ) ) dx ) \qquad ( 48 )$$

where E(.) is the statistical operator of expectation (i.e., average), H(.) is a Heaviside function (i.e., H(x)=1, x≥0, H(x)=0, x<0), n(x) is a deprotection function, t is a threshold of the resist model, Fₙ₍ₓ₎(.) is a cumulative distribution function (CDF) of a scalar random variable n(x). Thus, where n(x)>t, the resist is removed. In this way, the Heaviside function may be used to correlate that for all areas where n(x)>t, the value of the Heaviside function=1. As shown, the integration is over the defined area, in this instance SPCD. Other defined areas are contemplated.

Various distributions of scalar random variable n(x) are contemplated. As one example, for one example of the stochastic model, n(x) may comprise a Gaussian Random Field. As such, equation (48) results in:

$$APA = \frac{1}{2} {\int }_{SPCD} ( 1 - erf ( \frac{t - μ ( x )}{σ ( x ) \sqrt{2}} ) ) dx \qquad ( 49 )$$

where erf(.) is the Gauss error function, μ(x) is the mean deprotection, which may be calculated from the advanced resist model (e.g., the non-stochastic OPC resist model) or the stochastic model, σ(x) is a standard deviation (e.g., square root of the variance) of a random variable n(x) (i.e. the Gaussian Random Field sampled at the point x), which may be calculated from the stochastic model. Though n(x) is considered a Gaussian Random Field, other distributions, such as a continuous random field distribution, a multivariate normal distribution, or the like, are contemplated as well.

Further, the standard deviation (e.g., the sqrt(Var(A)), where A is the printed area) may be indicative of variation of the area of the printed features, which may be a probative stochastic metric characterizing the stochastic variability of certain features. The standard deviation printed area metric may be used alone or in combination with other metrics, such as any one, any combination, or all of: local critical dimension uniformity (LCDU); line width roughness (LWR) (e.g., measuring the distance between the edges of a line and calculating 3 times the standard deviation); or line edge roughness (LER) (e.g., measuring 3 times the standard deviation of the position of 1 edge).

The standard deviation printed area metric may be probative for the stochastic variability of various features that are designated for printing, such as via/CH patterns. For example, in the case of via/CH patterns, the standard deviation printed area metric may be probative because the electrical resistance of the wire is inversely proportional to the area of its cross-section (and not its critical dimension (CD) or any other linear measurement of its width used in other metrics). Thus, the standard deviation printed area metric is a probative lithographical metric to the cross-sectional area of the via. Further, the area of the SEM-imaged via on the wafer is easy to calculate from the contour of the SEM image. Compared to the calculation of CD from the SEM image, the calculation of such area does not require aligning the CD gauge to the (unknown) center of the target of the via. Finally, the standard deviation printed area metric may be efficiently analytically calculated, as shown below.

For Var(A), where A is the printed area:

$$Var ( A ) = E ( {A}^{2} ) - {( E ( A ) )}^{2} \qquad ( 50 )$$

For the first term in Equation (50):

$$E ( {A}^{2} ) = E ( {( {\int }_{V} H ( n ( x ) - t ) dx )}^{2} ) \qquad ( 51 )$$

$$E ( {A}^{2} ) = E ( \int {\int }_{VV} H ( n ( {x}_{1} ) - t ) H ( n ( {x}_{2} ) - t ) {dx}_{1} {dx}_{2} ) \qquad ( 52 )$$

$$E ( {A}^{2} ) = \int {\int }_{VV} E ( H ( n ( {x}_{1} ) - t ) H ( n ( {x}_{2} ) - t ) ) {dx}_{1} {dx}_{2} \qquad ( 53 )$$

$$E ( {A}^{2} ) = \int {\int }_{VV} ( 1 - {F}_{( n ( {x}_{1} ) , n ( {x}_{2} ) )} ( t , t ) ) {dx}_{1} {dx}_{2} \qquad ( 54 )$$

where V is the simulation domain in resist (interchangeably referred to as a simulation region), n(x) is deprotection (resist image), t is a printability threshold and H is a Heaviside function (H (x)=1, when x≥0, and (H (x)=0 otherwise). F₍ₙ₍ₓ_{₁}_{),n(x}_{₂}₎₎(t, t) denotes a CDF of a bivariate random variable (n(x₁), n(x₂)), where this CDF is evaluated at a point (t, t).

The second term in Equation (50), (E(A))², is the squared APA, calculated within the simulation domain V, for example, according to paragraphs [0240]-[0246]above, with SPCD integration area replaced by the simulation domain V.

In this regard, there is a random printed domain, or printed feature, with the area of this random domain/feature (A), being a random variable. V is a deterministic simulation domain, which may be user-selected, within which the user may seek to characterize a stochastic variation of a printed feature, such as a via. The user may thus select V to encompass the variations of the printed element (e.g., variations in the vias) that the user considers possible.

For instance, certain printed elements, such as vias, may be placed in periodic patterns. For these periodic via patterns, the adjacent vias may be placed sufficiently far as not to merge as a result of their stochastic fluctuations. All stochastic fluctuations of each via of interest to the user may then be bound to the period of the given via, with V selected to be this period. For the formula for Var(A) to represent the variance of a given via, the simulation domain may be selected such that for any possible stochastic perturbation of the given via, V includes this given via entirely, and V need not include any portion of any other neighboring vias. In other words, the formula for Var(A) may comprise a formula for the variance of the printed area within the user-selected domain V. If Var(A) is sought to represent the variance of a given via, the selected V may include this given via in all of its entirety, and need not include any other neighboring vias, for any stochastic fluctuations these vias may experience.

In the example of a sufficiently sparse rectangular arrays of vias where the vias are separated center-to-center in the x and y directions in Px and Py, one manner to select V (the simulation domain) for a respective via is to select V based on the dimensions of the array (e.g., select V to be an Px-by-Py rectangle centered on the respective via). In this way, the rectangular domain may be called a period of this via array.

For the current stochastic model (which may be based on the Gaussian Random Field deprotection (n(x)), an analytical calculation of the standard deviation of the printed area metric may be performed by calculating the CDF of the bivariate normal distribution (n(x₁), n(x₂)) at a point (t, t). The CDF of a bivariate normal distribution can be efficiently calculated by a numerical integration of the probability density function (PDF) of a bivariate normal distribution, see, e.g., Genz, A. Numerical computation of rectangular bivariate and trivariate normal and t probabilities. Statistics and Computing 14, 251-260 (2004). https://doi.org/10.1023/B:STCO.0000035304.20635.31

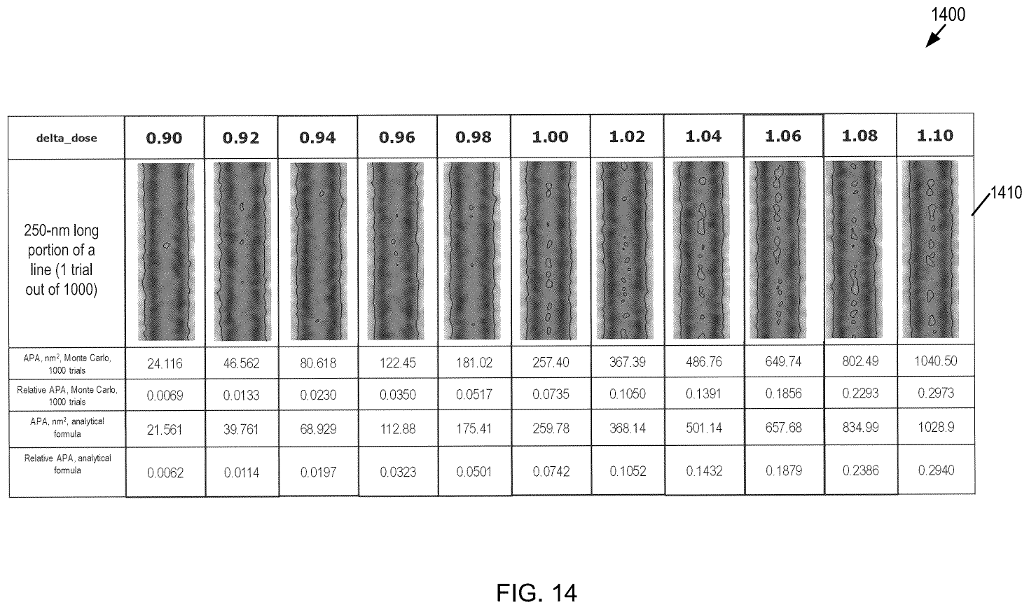

The analytical APA metric may be compared with the Monte Carlo simulation-based APA metric for a lines and spaces (LS) SRAF case. In particular, the table 1400 (with images of the SPCD 1410 for different doses) illustrated in FIG. 14 includes results for an EUV process for an LS array with pitch=80 nm, main feature linewidth=20 nm, the SRAF linewidth of 14 nm, dose=100 mJ/cm2, diffusion_length=3 nm, resist_efficiency=0.05, which results in APA relative to the design SRAF area of about 0.07-0.08. As shown in FIG. 14, the dose may be varied within −10% to +10% from the nominal, and APA relative to the design SRAF area is calculated, first using Monte Carlo simulations and second using the analytical formula for APA. Thus, as shown in the table 1400, the APA in nm² for the Monte Carlo simulations is based on 1,000 trials. The relative APA, both for the Monte Carlo simulations and the analytical APA, are derived based on dividing the APA by the area of 3,500 nm² (in the present case, the SPCD is 14 nm*250 nm=3,500 nm² centered rectangle, with the mask SRAF within 250 nm long line). It is noted that the agreement between the APA based on the Monte Carlo simulations and the analytical APA may be further improved by increasing the number of Monte Carlo trials.

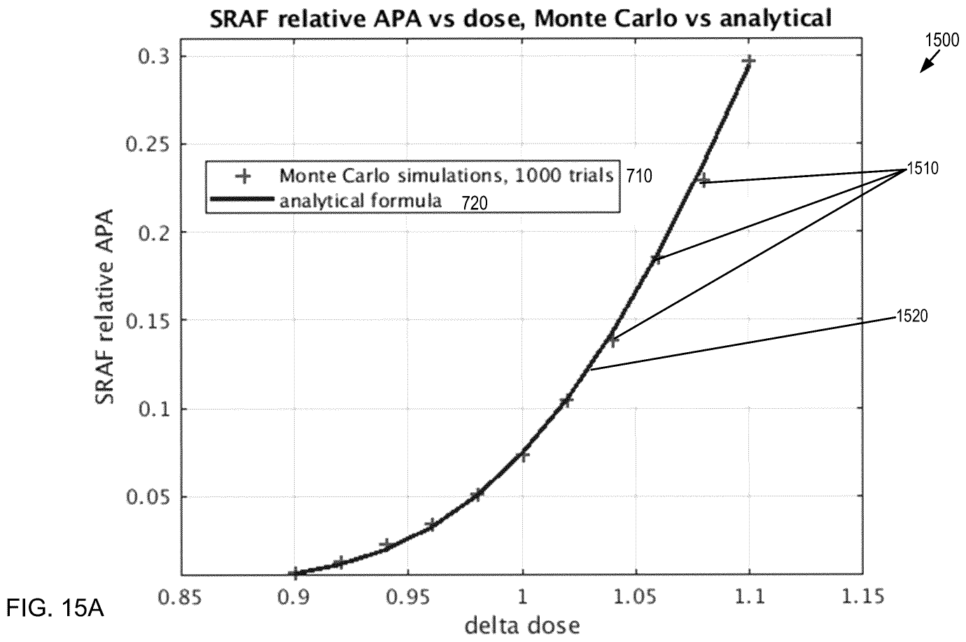

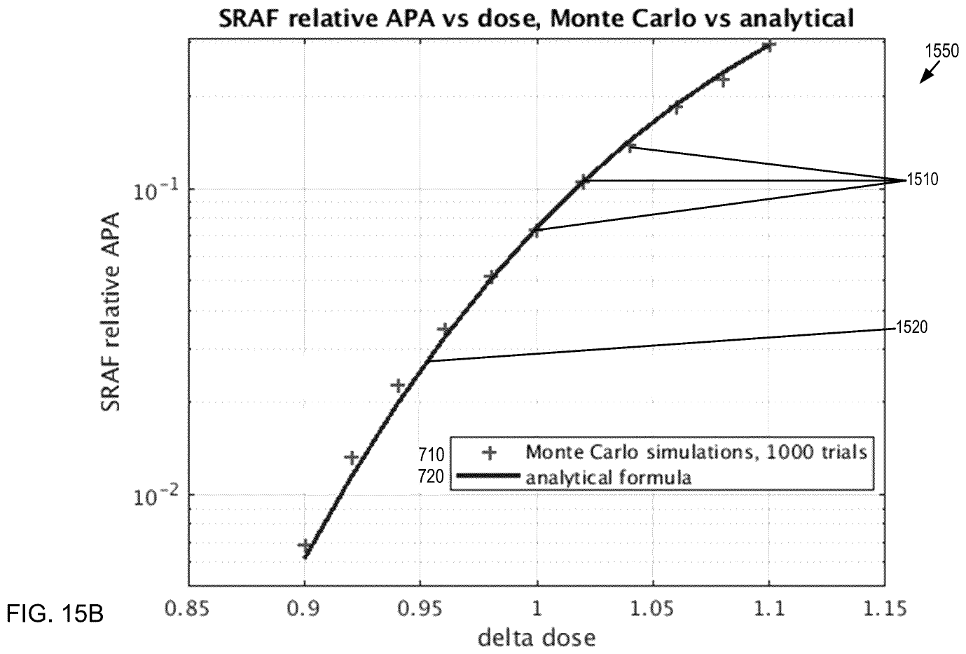

FIG. 15A is a graph 1500 of SRAF relative APA vs. dose for Monte Carlo and for analytical solutions (linear scale) for the data illustrated in FIG. 14. FIG. 15B is a graph 1550 of SRAF relative APA vs. dose for Monte Carlo and for analytical solutions (logarithmic scale) for the data illustrated in FIG. 14. As shown, the Monte Carlo simulation data points 1510 follow the curve of the analytical formula 1520.

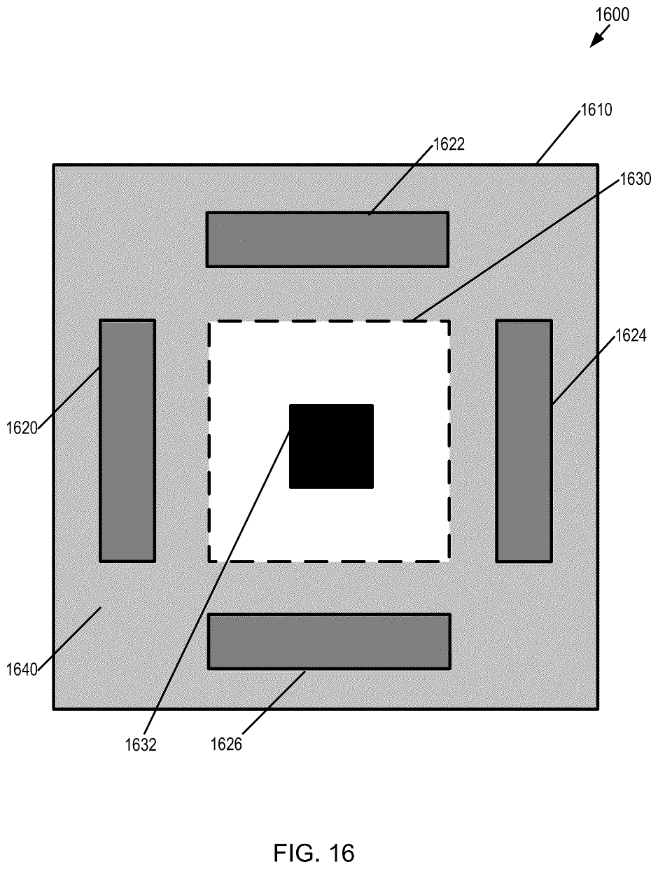

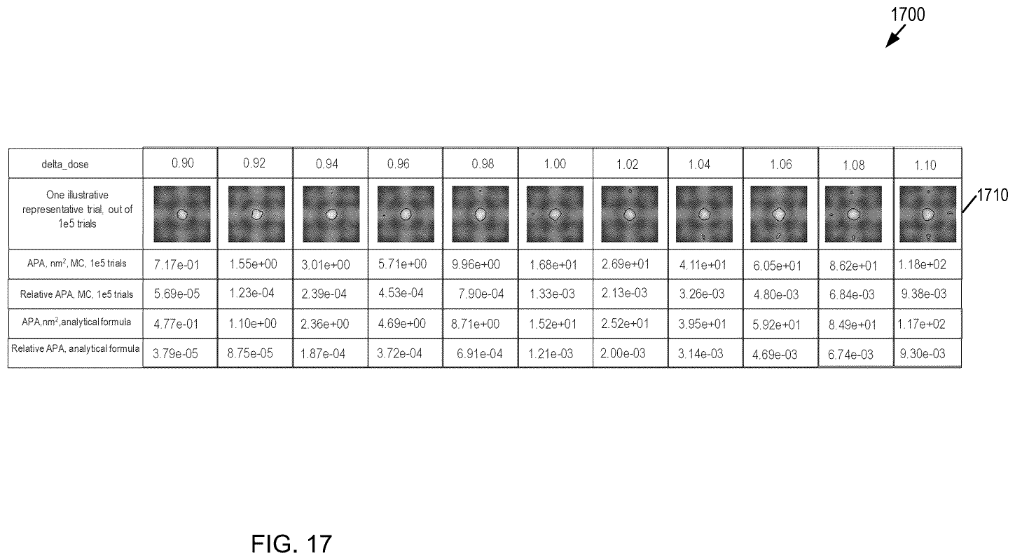

FIG. 16 is an illustration 1600 of the sidelobe printability control domain (SPCD) (defined by element 1640 between box 1610 and 1630) for a via/contact holes (CH) case (shown as main feature 1632). In the example of FIG. 16, the mask comprises: a darkfield mask; X/Y pitches 125 nm; main feature 1632 is 27×27 nm on the mask printing to the X/Y CDs of 25 nm on the wafer; and SRAFs 1620, 1622, 1624, 1626 are 10×54 nm, positioned with their geometrical centers at a distance of 44 nm from the center of the main feature 1632. The imaging and exposure comprises: a simplified imaging model (e.g., coherent illumination, Kirchhoff diffraction, EUV wavelength λ=13.5 nm, NA=0.33), nominal dose of 100 mJ/cm2). The resist and stochastic models comprise: diffusion_length=3 nm, resist efficiency=0.05. Further, the SRAF printability assessment comprises Sidelobe Printability Control Domain (SPCD) is the entire pitch, with the exception of the main feature 1632 (e.g., 54×54 nm square centered at the center of the pitch). The exposure dose may be varied within +/−10% of the nominal value in increments of 2%. Further, APA is calculated using 1e5 Monte Carlo trials and using the analytical APA metric, with the results from both calculations illustrated in the table 1700 (with images of the SPCD 1710 for different doses) in FIG. 17 showing SRAF-relative APA vs. dose derived from Monte Carlo simulations and from the analytical formula.

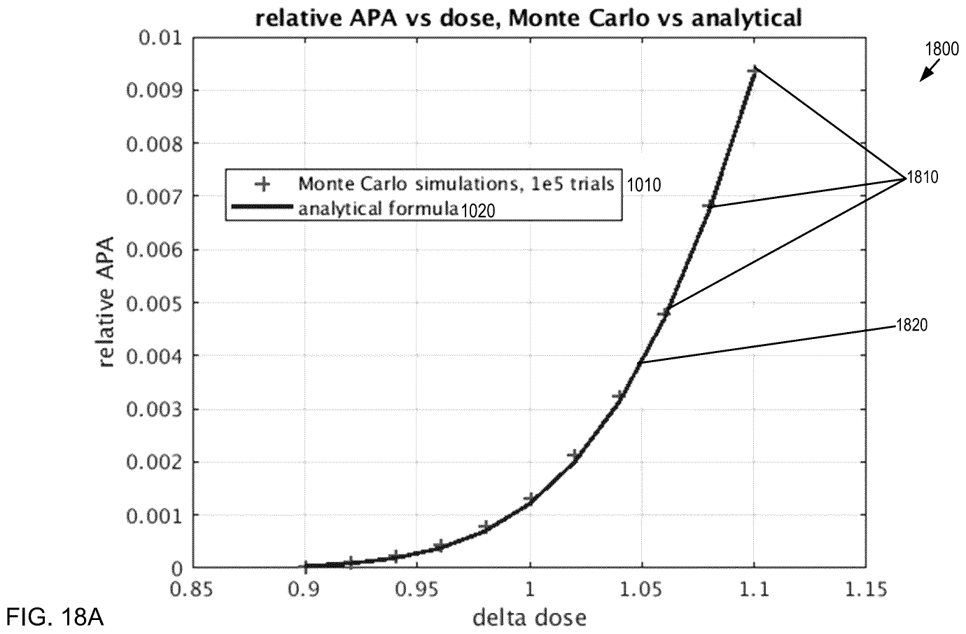

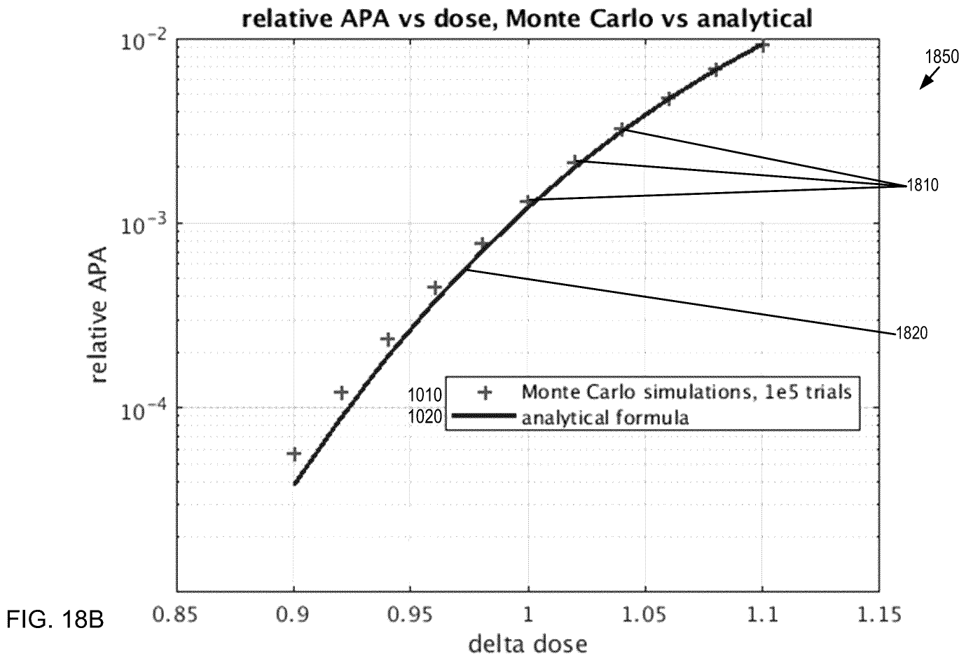

FIG. 18A is a graph 1800 of SRAF relative APA vs. dose for Monte Carlo and for analytical solutions (linear scale) for the data illustrated in FIG. 17. FIG. 18B is a graph 1850 of SRAF relative APA vs. dose for Monte Carlo and for analytical solutions (logarithmic scale) for the data illustrated in FIG. 17. As shown, the Monte Carlo simulation data points 1810 follow the curve of the analytical formula 1820.

As shown in FIGS. 15A-B and 18A-B, both LS and via/CH examples demonstrate a good agreement in SRAF APA prediction between the analytical APA metric and Monte Carlo derived APA. As discussed above, the stochastic model is based on Gaussian Random Field deprotection. Alternatively, the stochastic model may account for non-linearities in the real resist process (such as non-linearities to model saturation/depletion). In such an instance, the above analytical formulas for the printed area metrics likewise apply.

The above disclosed subject matter is to be considered illustrative, and not restrictive, and the appended claims are intended to cover all such modifications, enhancements, and other embodiments, which fall within the true spirit and scope of the description. Thus, to the maximum extent allowed by law, the scope is to be determined by the broadest permissible interpretation of the following claims and their equivalents, and shall not be restricted or limited by the foregoing detailed description.

1. A method, executed by at least one processor of at least one computer, for analyzing a lithographic process for imaging a portion of a layout design onto a substrate, the method comprising:
accessing a random field model configured to model stochastic randomness in one or both of exposure or resist process, the random field model configured to receive inputs of at least one light exposure parameter, at least one resist model parameter associated with resist used in the lithographic process, and at least one success or failure criterion, the random field model configured to generate a probability distribution function of deprotection concentration indicative of success probability or failure probability of the lithographic process;
inputting the at least one light exposure parameter, the at least one resist model parameter, and the at least one success or failure criterion to the random field model;
using the random field model to model the stochastic randomness for a plurality of levels based on one or both of the at least one light exposure parameter or the at least one resist model parameter, wherein the plurality of levels are discrete from one another in a resist thickness direction;
analyzing the stochastic randomness across the plurality of levels;
outputting, based on the analysis of the stochastic randomness across the plurality of levels, the indication of the success probability or the failure probability of the lithographic process; and
based on the indication of the success probability or the failure probability of the lithographic process, modifying at least one aspect in the lithographic process in order to reduce an effect of the stochastic randomness in the lithographic process.

2. The method of claim 1, wherein the one or both of the at least one light exposure parameter or the at least one resist model parameter includes at least one variable parameter;
wherein the at least one variable parameter has different values across the plurality of levels; and
wherein the random field model is configured to model the stochastic randomness for each level of a plurality of levels with the variable parameter.

3. The method of claim 2, wherein the at least one variable parameter includes an image intensity in a resist; and
wherein a value for the image intensity used in modeling the stochastic randomness for a level closer to or at a top surface of the resist is different from the value of the image intensity used in modeling the stochastic randomness for a level closer to or at a bottom surface of the resist.

4. The method of claim 2, wherein the at least one variable parameter includes a resist removal threshold; and
wherein a value for the resist removal threshold used to model the stochastic randomness for a level closer to or at a top surface of a resist is lower than the value for the resist removal threshold used to model the stochastic randomness for a level closer to or at a bottom surface of the resist.

5. The method of claim 4, wherein the values of the resist removal threshold decrease from the bottom surface to the top surface of the resist.

6. The method of claim 1, wherein the indication of the success probability or the failure probability of the lithographic process is based on a user-defined volume of interest.

7. The method of claim 1, wherein analyzing the stochastic randomness across the plurality of levels includes:
interpolating modeled values indicative of the stochastic randomness for each of the plurality of levels in order to generate a 3-dimentional distribution of the stochastic randomness.

8. The method of claim 7, further comprising calculating a top surface roughness (“TSR”) based on the 3-dimentional distribution of the stochastic randomness to indicate the success probability or the failure probability of the lithographic process.

9. The method of claim 7, further comprising calculating a power spectral density (“PSD”) based on the 3-dimentional distribution of the stochastic randomness to indicate the success probability or the failure probability of the lithographic process.

10. The method of claim 7, further comprising calculating an average printed volume (APV) relating to variation in printing due to the stochastic randomness in a user-defined volume of interest, based on the 3-dimentional distribution of the stochastic randomness, to determine a probability of a 3D sidelobe printing in the volume of interest.

11. The method of claim 7, further comprising calculating a standard deviation of a printed volume relating to variation in printing due to the stochastic randomness in a volume of interest based on the 3-dimentional distribution of the stochastic randomness to determine variability of a via in a resist.

12. One or more non-transitory computer-readable media storing computer-executable instructions for causing one or more processors performance of a method comprising:
accessing a random field model configured to model stochastic randomness in one or both of exposure or resist process, the random field model configured to receive inputs of at least one light exposure parameter, at least one resist model parameter associated with resist used in a lithographic process, and at least one success criterion or failure criterion, the random field model configured to generate a probability distribution function of deprotection concentration indicative of success probability or failure probability of the lithographic process;
inputting the at least one light exposure parameter, the at least one resist model parameter, and the at least one success criterion or failure criterion to the random field model;
using the random field model to model the stochastic randomness for a plurality of levels based on one or both of the at least one light exposure parameter or the at least one resist model parameter, wherein the plurality of levels are discrete from one another in a resist thickness direction;
analyzing the stochastic randomness across the plurality of levels;
outputting, based on the analysis of the stochastic randomness across the plurality of levels, the indication of the success probability or the failure probability of the lithographic process; and
based on the indication of the success probability or the failure probability of the lithographic process, modifying at least one aspect in the lithographic process in order to reduce an effect of the stochastic randomness in the lithographic process.

13. The one or more non-transitory computer-readable media of claim 12, wherein the one or both of the at least one light exposure parameter or the at least one resist model parameter includes at least one variable parameter;
wherein the at least one variable parameter has different values across the plurality of levels; and
wherein the random field model is configured to model the stochastic randomness for each level of a plurality of levels with the variable parameter.

14. The one or more non-transitory computer-readable media of claim 13, wherein the at least one variable parameter includes an image intensity in a resist; and
wherein a value for the image intensity used in modeling the stochastic randomness for a level closer to or at a top surface of the resist is different from the value of the image intensity used in modeling the stochastic randomness for a level closer to or at a bottom surface of the resist.

15. The one or more non-transitory computer-readable media of claim 13, wherein the at least one variable parameter includes a resist removal threshold; and
wherein a value for the resist removal threshold used to model the stochastic randomness for a level closer to or at a top surface of a resist is lower than the value for the resist removal threshold used to model the stochastic randomness for a level closer to or at a bottom surface of the resist.

16. The one or more non-transitory computer-readable media of claim 15, wherein the values of the resist removal threshold decrease from the bottom surface to the top surface of the resist.

17. The one or more non-transitory computer-readable media of claim 12, wherein the indication of the success probability or the failure probability of the lithographic process is based on a user-defined volume of interest.

18. The one or more non-transitory computer-readable media of claim 12, wherein analyzing the stochastic randomness across the plurality of levels includes:
interpolating modeled values indicative of the stochastic randomness for each of the plurality of levels in order to generate a 3-dimentional distribution of the stochastic randomness.

19. A system comprising: one or more processors, the one or more processors programmed to perform:
accessing a random field model configured to model stochastic randomness in one or both of exposure or resist process, the random field model configured to receive inputs of at least one light exposure parameter, at least one resist model parameter associated with resist used in a lithographic process, and at least one success or failure criterion, the random field model configured to generate a probability distribution function of deprotection concentration indicative of success probability or failure probability of the lithographic process;
inputting the at least one light exposure parameter, the at least one resist model parameter, and the at least one success or failure criterion to the random field model;
using the random field model to model the stochastic randomness for a plurality of levels based on one or both of the at least one light exposure parameter or the at least one resist model parameter, wherein the plurality of levels are discrete from one another in a resist thickness direction;
analyzing the stochastic randomness across the plurality of levels;
outputting, based on the analysis of the stochastic randomness across the plurality of levels, the indication of the success probability or the failure probability of the lithographic process; and
based on the indication of the success probability or the failure probability of the lithographic process, modifying at least one aspect in the lithographic process in order to reduce an effect of the stochastic randomness in the lithographic process.

20. The system of claim 19, wherein the one or both of the at least one light exposure parameter or the at least one resist model parameter includes at least one variable parameter;
wherein the at least one variable parameter has different values across the plurality of levels; and
wherein the random field model is configured to model the stochastic randomness for each level of a plurality of levels with the variable parameter.
